(19) United States
(12) Patent Application Publication
(10) Pub. No.: US 2025/0038115 A1
(43) Pub. Date: Jan. 30, 2025

(54) SEMICONDUCTOR PACKAGE

(71) Applicant: SAMSUNG ELECTRONICS CO., LTD., SUWON-SI (KR)

(72) Inventor: JUNGHOON KANG, Suwon-Si (KR)

(21) Appl. No.: 18/438,357

(22) Filed: Feb. 9, 2024

(30) Foreign Application Priority Data
Jul. 25, 2023 (KR) 10-2023-0096857

(51) Int. Cl. H01L 23/538; H01L 23/00; H01L 23/31; H01L 25/065

(52) U.S. Cl. CPC H01L 23/5385; H01L 23/3121; H01L 23/5383; H01L 23/5384; H01L 24/08; H01L 24/48; H01L 25/0655; H01L 2224/08225; H01L 2224/48227

(57) ABSTRACT

A semiconductor package includes a lower redistribution substrate, a module structure on the lower redistribution substrate, a connection substrate on the lower redistribution substrate and at sides of the module structure, a dielectric member on the lower redistribution substrate between the connection substrate and the module structure, and an upper redistribution substrate on the dielectric member. The module structure includes an interposer substrate, a first semiconductor chip, and a molding layer. The molding layer and the dielectric member include different materials. A first via in a first vertical hole vertically penetrates the dielectric member and the molding layer. The first via connects a wiring pattern of the upper redistribution substrate to a top surface of the first semiconductor chip.

### CROSS-REFERENCE TO RELATED APPLICATION

This application claims priority under 35 U.S.C § 119 to Korean Patent Application No. 10-2023-0096857, filed on Jul. 25, 2023, in the Korean Intellectual Property Office, the disclosure of which is hereby incorporated by reference in its entirety.

### TECHNICAL FIELD

The present inventive concepts relate to a semiconductor package and a method of fabricating the same, and more particularly, to a semiconductor package including a connection substrate and a method of fabricating the same.

### DISCUSSION OF RELATED ART

A semiconductor package may be provided to implement an integrated circuit chip suitable for use in electronic products. The semiconductor package may be designed for compact size, low weight, and/or reduced manufacturing cost.

For example, a size of semiconductor chip may be reduced with high integration designs. However, it may be difficult to adhere, handle, and test the semiconductor chip as a size of the semiconductor chip is reduced. Additionally, diversified mount boards configured for semiconductor chips of various sizes may not be readily available.

A fan-out panel level package may be used to adapt a board for various semiconductor chips. In the case of fan-out panel semiconductor packages, an area of redistribution lines may be greater than that of the semiconductor chip.

### SUMMARY

Some embodiments of the present inventive concepts provide a semiconductor package with increased thermal radiation efficiency and a method of fabricating the same.

Some embodiments of the present inventive concepts provide a semiconductor package with improved electrical properties and a method of fabricating the same.

According to some embodiments of the present inventive concepts, a semiconductor package may comprise: a lower redistribution substrate; a module structure on the lower redistribution substrate; a connection substrate on the lower redistribution substrate and at sides of the module structure; a dielectric member on the lower redistribution substrate between the connection substrate and the module structure; and an upper redistribution substrate on the dielectric member. The module structure may include: an interposer substrate; a first semiconductor chip wire-bonded to the interposer substrate; and a molding layer on the interposer substrate and covering the first semiconductor chip. The molding layer and the dielectric member may include different materials. A first via may be in a first vertical hole that vertically penetrates the dielectric member and the molding layer. The first via may connect a wiring pattern of the upper redistribution substrate to a top surface of the first semiconductor chip.

According to some embodiments of the present inventive concepts, a semiconductor package may comprise: a lower redistribution substrate; a module structure on the lower redistribution substrate; an upper redistribution substrate on the lower redistribution substrate; a connection substrate between the lower redistribution substrate and the upper redistribution substrate, and at sides of the module structure; and a dielectric member disposed between the connection substrate and the module structure and disposed between the module structure and the upper redistribution substrate. The module structure may include: an interposer substrate; a first semiconductor chip and a second semiconductor chip on the interposer substrate; and a molding layer that covers the first semiconductor chip and the second semiconductor chip on the interposer substrate. The first semiconductor chip may be wire-bond mounted on the interposer substrate. The second semiconductor chip may be face-down disposed on the interposer substrate. A wiring pattern of the upper redistribution substrate may include a first via that vertically penetrates the dielectric member and the molding layer to come into connection with a top surface of at least one of the first semiconductor chip or the second semiconductor chip.

According to some embodiments of the present inventive concepts, a semiconductor package may comprise: a lower redistribution substrate; a connection substrate on the lower redistribution substrate, wherein the connection substrate has an opening that vertically penetrates the connection substrate; a module structure on the lower redistribution substrate and in the opening of the connection substrate; a dielectric member on the lower redistribution substrate and covering the module structure; and an upper redistribution substrate on the dielectric member. The module structure may include: an interposer substrate formed of glass; a first semiconductor chip wire-bonded to the interposer substrate; a thermal radiation member on a top surface of the first semiconductor chip and electrically insulated from the first semiconductor chip; a second semiconductor chip on the interposer substrate and spaced apart from the first semiconductor chip; and a molding layer on the interposer substrate and covering the first semiconductor chip and the second semiconductor chip. A wiring pattern of the upper redistribution substrate may include a first via that vertically penetrates the dielectric member and the molding layer to be coupled to one of the thermal radiation member or a rear surface of the second semiconductor chip. A first width of the first via in the dielectric member may be uniform. A second width of the first via in the molding layer may decrease with decreasing distance from the interposer substrate.

### BRIEF DESCRIPTION OF DRAWINGS

FIG. 1 illustrates a cross-sectional view showing a semiconductor package according to some embodiments of the present inventive concepts.

FIG. 2, FIG. 3, and FIG. 4 illustrate enlarged views section A of FIG. 1.

FIG. 5 illustrates a cross-sectional view showing a semiconductor package according to some embodiments of the present inventive concepts.

FIG. 6 illustrates an enlarged view showing section B of FIG. 5.

FIG. 7 illustrates a cross-sectional view showing a semiconductor package according to some embodiments of the present inventive concepts.

FIG. 8, FIG. 9, and FIG. 10 illustrate enlarged views showing section C of FIG. 7.

FIG. 11 illustrates a cross-sectional view showing a semiconductor package according to some embodiments of the present inventive concepts.

FIG. 12 illustrates an enlarged view showing section D of FIG. 11.

FIG. 13 illustrates a cross-sectional view showing a semiconductor package according to some embodiments of the present inventive concepts.

FIG. 14 illustrates an enlarged view showing section E of FIG. 13.

FIG. 15 and FIG. 16 illustrate cross-sectional views showing a semiconductor package according to some embodiments of the present inventive concepts.

FIGS. 17 to 28 illustrate cross-sectional views showing a method of fabricating a semiconductor package according to some embodiments of the present inventive concepts.

### DETAILED DESCRIPTION

The inventive concept may be implemented in various modifications and have various forms, and specific embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In the drawings, the thickness, the ratio, and the dimension of the elements may be exaggerated for effective description of the technical contents.

The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms unless the context clearly indicates otherwise.

Also, the terms such as “below”, “lower”, “above”, “upper” or the like, may be used in the description to describe one element's relationship to another element illustrated in the figures. It will be understood that the terms have a relative concept and may be described on the basis of the orientation depicted in the figures.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

The following will now describe a semiconductor package according to the present inventive concepts with reference to the accompanying drawings.

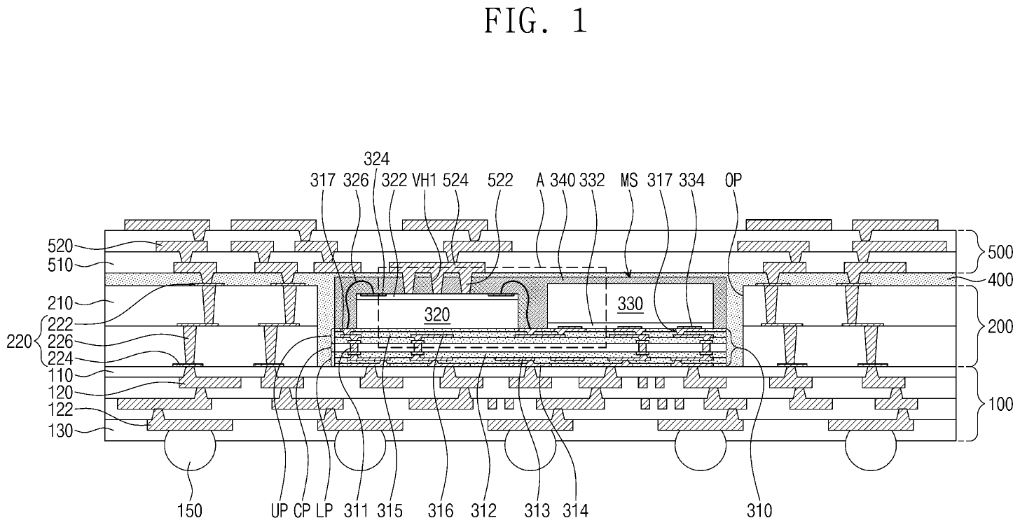

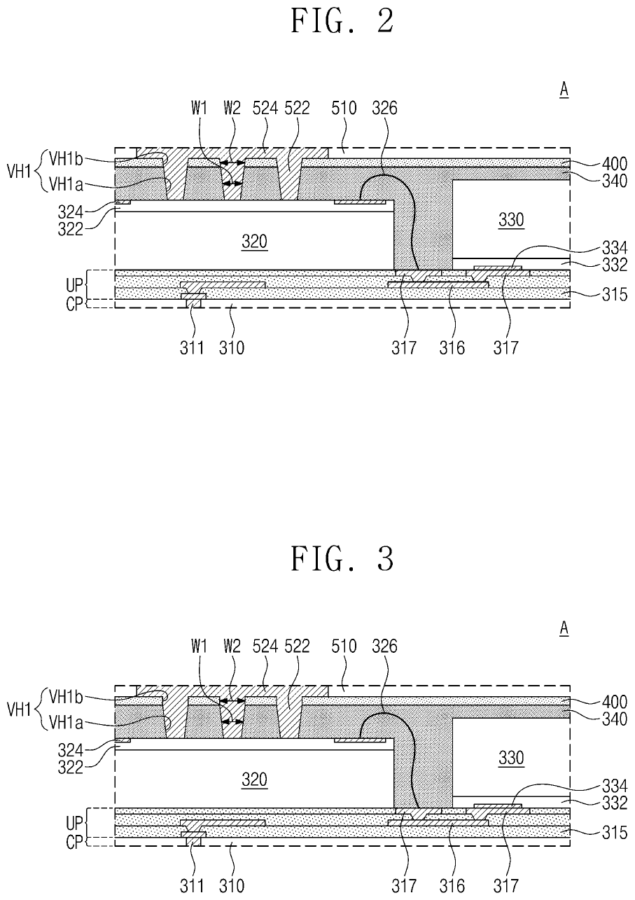

FIG. 1 illustrates a cross-sectional view showing a semiconductor package according to some embodiments of the present inventive concepts. FIG. 2, FIG. 3, and FIG. 4 illustrate enlarged views section A of FIG. 1.

Referring to FIG. 1 and FIG. 2, a first redistribution substrate 100 may be provided. The first redistribution substrate 100 may include one or more first substrate wiring layers. The first substrate wiring layers may be stacked on each other. Each of the first substrate wiring layers may include a first substrate dielectric pattern 110 and a first substrate wiring pattern 120. The first substrate wiring pattern 120 may be disposed in the first substrate dielectric pattern 110. The first substrate wiring pattern 120 disposed in a first substrate wiring layer may be electrically connected to the first substrate wiring pattern 120 in an adjacent first substrate wiring layer. The following description focuses on an example in which one first substrate wiring layer is used to explain a configuration of the first substrate dielectric pattern 110 and the first substrate wiring pattern 120.

The first substrate dielectric pattern 110 may include a polymer. The first substrate dielectric pattern 110 may include a dielectric polymer or a photo-imageable dielectric (PID). For example, the photo-imageable dielectric may include at least one selected from photosensitive polyimide, polybenzoxazole (PBO), phenolic polymers, or benzocyclobutene polymers. In an embodiment, the first substrate dielectric pattern 110 may include a dielectric material. For example, the first substrate dielectric pattern 110 may include silicon oxide (SiO), silicon nitride (SiN), silicon oxynitride (SiON), or a dielectric polymer.

The first substrate wiring pattern 120 may be disposed on a bottom surface of the first substrate dielectric pattern 110. The first substrate wiring pattern 120 may horizontally extend on the bottom surface of the first substrate dielectric pattern 110. The first substrate wiring pattern 120 may protrude into the bottom surface of the first substrate dielectric pattern 110. The first substrate wiring pattern 120 may protrude into the bottom surface of the first substrate dielectric pattern 110 and extend to a top surface of the first substrate dielectric pattern 110. The first substrate wiring pattern 120 may be exposed by the top surface of the first substrate dielectric pattern 110.

On the bottom surface of the first substrate dielectric pattern 110, the first substrate wiring pattern 120 may be covered with an underlying first substrate dielectric pattern 110. The first substrate wiring pattern 120 provided in a lowermost first substrate wiring layer may be substrate pads 122 coupled to external terminals 150. As discussed above, the first substrate wiring pattern 120 may be a pad or line part of the first substrate wiring layer. In this sense, the first substrate wiring pattern 120 may be a component for horizontal redistribution in the first redistribution substrate 100. For example, the first substrate wiring pattern 120 may redistribute a signal or power. The first substrate wiring pattern 120 may include a conductive material. For example, the first substrate wiring pattern 120 may include metal, such as copper (Cu).

The first substrate wiring pattern 120 may have a damascene structure. For example, the first substrate wiring pattern 120 may have a via that protrudes from a top surface thereof. The via may be a component for connecting the first substrate wiring patterns 120 to each other. The via may connect vertically adjacent ones of the first substrate wiring patterns 120 to each other. For example, the via may extend from the top surface of the first substrate wiring pattern 120, and the via may penetrate the first substrate dielectric pattern 110 to be coupled to a bottom surface of the first substrate wiring pattern 120 in an overlying first substrate wiring layer. In an embodiment, the via may be a component for connecting the first substrate wiring pattern 120 of an uppermost first substrate wiring layer to a connection substrate 200 or a module structure MS. For example, the via may extend from the top surface of the first substrate wiring pattern 120, and the via may penetrate an uppermost first substrate dielectric pattern 110 to be coupled to a connection substrate 200 or a module structure MS. In an embodiment, a lower portion of the first substrate wiring pattern 120 positioned on the bottom surface of the first substrate dielectric pattern 110 may be a head part used as a horizontal line or pad, and the via of the first substrate wiring pattern 120 may be a tail part. The first substrate wiring pattern 120 may have an inverse T shape.

A substrate protection layer 130 may be provided on a bottom surface of the lowermost first substrate wiring layer. The substrate protection layer 130 may cover the substrate pads 122. According to some embodiments, the substrate protection layer 130 encapsulate a portion of the substrate pads 122. The substrate pads 122 may be include a via protruding from a top surface thereof and a top surface of the substrate protection layer 130. The substrate protection layer 130 may expose a portion of the bottom surfaces of the substrate pads 122. The substrate protection layer 130 may cover a portion of the bottom surface of the substrate pads 122. The substrate protection layer 130 may include a dielectric polymer or a photo-imageable dielectric (PID).

The substrate pads 122 may be provided with external terminals 150 on the bottom surfaces thereof. For example, the external terminals 150 may penetrate the substrate protection layer 130 to be coupled to the substrate pads 122. The external terminals 150 may include solder balls or solder bumps. Based on type and arrangement of the external terminals 150, a semiconductor package may be provided in the form of a ball grid array (BGA) type, a fine ball-grid array (FBGA) type, or a land grid array (LGA) type.

According to an embodiment and referring to FIG. 1, a semiconductor package may be provided as a fan-out panel level package (FO-PLP). For example, a connection substrate 200 may be provided on the first redistribution substrate 100. The connection substrate 200 may have an opening OP. The opening OP may penetrate the connection substrate 200. For example, the opening OP may be shaped like an open hole that connects top and bottom surfaces of the connection substrate 200. The opening OP may define a space accommodating a module structure MS. For example, the connection substrate 200 may be disposed at sides of the module structure MS. The bottom surface of the connection substrate 200 may be in contact with a top surface of the first redistribution substrate 100.

The present inventive concepts, however, are not limited thereto. For example, when a semiconductor package is fabricated in a chip-last scheme, the bottom surface of the connection substrate 200 may be spaced apart from the top surface of the first redistribution substrate 100. For example, the connection substrate 200 may be connected to the first redistribution substrate 100 through a discrete terminal such as a micro-solder ball. The following description will focus on FIG. 1.

The connection substrate 200 may include a base layer 210 and a conductive member 220. The conductive member 220 may be a line pattern provided in the base layer 210. The base layer 210 may be provided as a plurality of layers stacked on each other.

The conductive member 220 may have a line structure that vertically connects the first redistribution substrate 100 to a second redistribution substrate 500. The conductive member 220 may be disposed between the opening OP and an outer surface of the connection substrate 200. The conductive member 220 may include upper pads 222, lower pads 224, and vias 226.

The upper pads 222 may be disposed on the top surface of the connection substrate 200. The upper pads 222 may protrude onto the top surface of the connection substrate 200. Differently from a configuration shown, the upper pads 222 may be buried in the base layer 210, and top surfaces of the upper pads 222 may be coplanar with the top surface of the connection substrate 200.

The lower pads 224 may be disposed on the bottom surface of the connection substrate 200. The lower pads 224 may be buried in the base layer 210, and bottom surfaces of the lower pads 224 may be coplanar with the bottom surface of the connection substrate 200. The vias 226 may penetrate the base layer 210, and may electrically connect the upper pads 222 to the lower pads 224.

The vias 226 may be stacked in multiple base layers. The vias 226 may be connected by a middle pad. For example, the middle pad may be substantially the same of the upper pads 222. A lower via of the vias 226 may contact a lower surface of the middle pad and an upper via of the vias 226 may contact an upper surface of the middle pad.

The base layer 210 may include a polymer. For example, the base layer 210 may include a dielectric polymer or a photo-imageable dielectric (PID). For example, the photo-imageable dielectric may include at least one selected from photosensitive polyimide, polybenzoxazole (PBO), phenolic polymers, or benzocyclobutene polymers. In an embodiment, the base layer 210 may include a dielectric material. For example, the base layer 210 may include silicon oxide (SiO), silicon nitride (SiN), silicon oxynitride (SiON), or a dielectric polymer. The upper pads 222, the lower pads 224, and the vias 226 may include a conductor or metal, such as copper (Cu). The upper pads 222, the lower pads 224, and the vias 226 may include the same conductor or different conductors.

The connection substrate 200 may be mounted on the first redistribution substrate 100. For example, the connection substrate 200 may be in contact with the first redistribution substrate 100. The first substrate wiring pattern 120 in the uppermost first substrate wiring layer may penetrate the uppermost first substrate dielectric pattern 110 and may be coupled to the lower pads 224. Therefore, the connection substrate 200 may be electrically connected through the first redistribution substrate 100 to the external terminals 150 or a module structure MS.

A module structure MS may be disposed on the first redistribution substrate 100. The module structure MS may be disposed in the opening OP of the connection substrate 200. In this case, the module structure MS may be disposed on a portion of the first redistribution substrate 100 exposed by the opening OP. The module structure MS may be in contact with the top surface of the first redistribution substrate 100. The module structure MS may be spaced apart from the connection substrate 200, for example, from an inner sidewall of the opening OP. The module structure MS may have a top surface at a level from the first redistribution substrate 100 disposed higher than a level of the top surface of the connection substrate 200. For example, the module structure MS may have a height greater than a height of the connection substrate 200. For another example, the module structure MS may have a height the same as or less than the height of the connection substrate 200. A configuration of the module structure MS will be discussed in detail below.

The module structure MS may include an interposer substrate 310, and may also include a first semiconductor chip 320 and a second semiconductor chip 330 that are disposed on the interposer substrate 310. For example, the first semiconductor chip 320 may be disposed adjacent to the second semiconductor chip 330 on the interposer substrate 310.

The interposer substrate 310 may include a core portion CP, an upper buildup portion UP, and a lower buildup portion LP.

The core portion CP may extend in a direction. The core portion CP may include a core pattern that extends when viewed in plan. Embodiments of the present inventive concepts may be explained by way of an example including the core portion CP having a core pattern, but the present inventive concepts are not limited thereto. The core portion CP may include a dielectric material. For example, the core portion CP may include a of glass plates, glass fibers, ceramic plates, epoxy, and resin. For example, the interposer substrate 310 may be a glass substrate. For another example, the core portion CP may include one selected from stainless steels, aluminum (Al), nickel (Ni), magnesium (Mg), zinc (Zn), or tantalum (Ta), or any combination thereof.

The core portion CP may have a vertical connection terminal 311 that vertically penetrates the core portion CP. The vertical connection terminal 311 may extend from top to bottom surfaces of the core portion CP. The vertical connection terminal 311 may have pad parts positioned on the top and bottom surfaces of the core portion CP and a via par that vertically penetrates the core portion CP to vertically connect the pad parts to each other. The pad parts of the vertical connection terminal 311 may be provided in the form of either a discrete component separated from the via part of the vertical connection terminal 311 or a single unitary body with the via part of the vertical connection terminal 311. In an embodiment, the vertical connection terminal 311 may have no pad parts. For example, the vertical connection terminal 311 may have a top surface coplanar with the top surface of the core portion CP, and may have a bottom surface coplanar with the bottom surface of the core portion CP. A plurality of vertical connection terminals 311 may be provided. The vertical connection terminals 311 may include a conductive material or a metallic material, such as copper (Cu).

The lower buildup portion LP may cover the bottom surface of the core portion CP. The lower buildup portion LP may include lower dielectric patterns 312 and lower wiring patterns 313 that are stacked on the bottom surface of the core portion CP. The lower wiring patterns 313 may be connected to the vertical connection terminals 311. For example, an uppermost lower dielectric pattern 312 may be in contact with the bottom surface of the core portion CP, and some of the lower wiring patterns 313 may penetrate the uppermost lower dielectric pattern 312 to come into contact with the vertical connection terminals 311. A lowermost lower dielectric pattern 312 may expose some of the lower wiring patterns 313, and the exposed lower wiring patterns 313 may correspond to first interposer pads 314 for coupling the interposer substrate 310 to the first redistribution substrate 100.

The upper buildup portion UP may cover the top surface of the core portion CP. For example, the upper buildup portion UP may be disposed opposite the lower buildup portion LP, with the core portion CP disposed therebetween. The upper buildup portion UP may include upper dielectric patterns 315 and upper wiring patterns 316 that are stacked on the top surface of the core portion CP. The upper wiring patterns 316 may be connected to the vertical connection terminals 311 of the core portion CP. For example, a lowermost upper dielectric pattern 315 may be in contact with the top surface of the core portion CP, and some of the upper wiring patterns 316 may penetrate the lowermost upper dielectric pattern 315 to come into contact with the vertical connection terminals 311. In this sense, the upper wiring patterns 316 may be electrically connected through the vertical connection terminals 311 to the lower wiring patterns 313. An uppermost upper dielectric pattern 315 may expose some of the upper wiring patterns 316, and the exposed upper wiring patterns 316 may correspond to second interposer pads 317 for mounting the first semiconductor chip 320 and the second semiconductor chip 330 on the interposer substrate 310.

The first semiconductor chip 320 and the second semiconductor chip 330 may be disposed on the interposer substrate 310. The first semiconductor chip 320 and the second semiconductor chip 330 may be horizontally spaced apart from each other. The first semiconductor chip 320 and the second semiconductor chip 330 may be of the same type or of different types. For example, the first semiconductor chip 320 and the second semiconductor chip 330 may both be memory chips, or the first semiconductor chip 320 may be a memory chip and the second semiconductor chip 330 may be a logic chip. The present inventive concepts, however, are not limited thereto. The first semiconductor chip 320 and the second semiconductor chip 330 may have a same size or different sizes, for example, different heights and widths.

The first semiconductor chip 320 may include a semiconductor material, such as silicon (Si). The first semiconductor chip 320 may include a first circuit layer 322. The first circuit layer 322 may include a radio frequency integrated circuit (RF IC). In an embodiment, the first circuit layer 322 may further include various electronic devices for driving the radio frequency integrated circuit, such as a modem, a transceiver, a power amplifier module (PAM), a frequency filter, or a low noise amplifier (LNA). In this sense, the first semiconductor chip 320 may be a radio frequency (RF) chip. In an embodiment, the first circuit layer 322 may include a logic circuit or a memory circuit. In this sense, the first semiconductor chip 320 may be a logic chip or a memory chip. In some embodiments of the present inventive concepts, the first circuit layer 322 may include various integrated circuits. The first semiconductor chip 320 may have first chip pads 324 provided on a surface of the first circuit layer 322.

The first semiconductor chip 320 may be disposed in a face-up state on the interposer substrate. For example, the first semiconductor chip 320 may have a rear surface directed toward the interposer substrate 310 and a front surface opposite to the rear surface. In this description, the term “front surface” may be defined to indicate a surface or an active surface on which pads of a semiconductor chip or module may be formed, and term “rear surface” may be defined to indicate another surface opposite to the front surface. Based on a position of the first semiconductor chip 320, a bottom surface of the first semiconductor chip 320 may correspond to a rear surface of the first semiconductor chip 320, and a top surface of the first semiconductor chip 320 may correspond to a front surface of the first semiconductor chip 320. For example, the first circuit layer 322 of the first semiconductor chip 320 may be provided on the top surface of the first semiconductor chip 320. The bottom surface of the first semiconductor chip 320 may be in contact with a top surface of the interposer substrate 310.

The first semiconductor chip 320 may be mounted on the second interposer pads 317. The first semiconductor chip 320 may be wire-bond mounted on the interposer substrate 310. Although not shown, the first semiconductor chip 320 may be attached through an adhesion layer to the top surface of the interposer substrate 310. The first chip pads 324 may be exposed on the top surface of the first semiconductor chip 320. The first chip pads 324 may be connected through bonding wires 326 to the second interposer pads 317. For example, each of the bonding wires 326 may extend from a top surface of a first chip pad of the first chip pads 324 toward a top surface of a second interposer pad of the second interposer pads 317.

The second semiconductor chip 330 may include a semiconductor material, such as silicon (Si). The second semiconductor chip 330 may include a second circuit layer 332. The second circuit layer 332 may include a logic circuit or a memory circuit. In this sense, the second semiconductor chip 330 may be a logic chip or a memory chip. In some embodiments of the present inventive concepts, the second circuit layer 332 may include various integrated circuits. The second semiconductor chip 330 may have second chip pads 334 provided on a surface of the second circuit layer 332.

The second semiconductor chip 330 may be disposed in a face-down state on the interposer substrate 310. The second semiconductor chip 330 may be face-down mounted on the interposer substrate 310. For example, the second semiconductor chip 330 may have a front surface directed toward the interposer substrate 310 and a rear surface opposite to the front surface. Based on a position of the second semiconductor chip 330, a bottom surface of the second semiconductor chip 330 may correspond to a front surface of the second semiconductor chip 330, and a top surface of the second semiconductor chip 330 may correspond to a rear surface of the second semiconductor chip 330. For example, the second circuit layer 332 of the second semiconductor chip 330 may be provided on the bottom surface of the second semiconductor chip 330. The bottom surface of the second semiconductor chip 330, or a bottom surface of the second circuit layer 332 may be in contact with the top surface of the interposer substrate 310. A plurality of second semiconductor chips 330 may be provided. In this case, the plurality of second semiconductor chips 330 may have a vertical chip stack structure.

The second semiconductor chip 330 may be mounted on the second interposer pads 317. The second semiconductor chip 330 may be direct-bond mounted on the interposer substrate 310. The second semiconductor chip 330 may be in contact with the interposer substrate 310. For example, the second circuit layer 332 of the second semiconductor chip 330 may be in contact with the upper buildup portion UP of the interposer substrate 310. The second chip pads 334 may be in contact with the second interposer pads 317.

The second chip pads 334 may be directly connected to the second interposer pads 317. For example, an intermetallic bonding may be achieved between the second chip pads 334 and the second interposer pads 317. In this description, the term “hybrid bonding” may denote a bonding in which two components of the same kind are merged at an interface therebetween. For example, a continuous configuration may be provided between the second chip pad 334 and the second interposer pad 317 that are bonded to each other, and an invisible interface may be present between the second chip pad 334 and the second interposer pad 317. The invisible interface may be an interface that does not appear on inspection. For example, the second chip pad 334 and the second interposer pad 317 may appear, upon inspect, to be a same component. The second chip pad 334 and the second interposer pad 317 may be formed of the same material and provided in the form of a component. For example, the second chip pad 334 and the second interposer pad 317 may be connected to constitute a single unitary body.

The first semiconductor chip 320 and the second semiconductor chip 330 may be electrically connected through the interposer substrate 310. For example, some of the second interposer pads 317 to which the bonding wires 326 of the first semiconductor chip 320 are connected and some of the second interposer pads 317 to which the second chip pads 334 of the second semiconductor chip 330 are connected may be electrically connected through the upper wiring pattern 316 of the upper buildup portion UP of the interposer substrate 310. The present inventive concepts, however, are not limited thereto, and the first semiconductor chip 320 and the second semiconductor chip 330 may not be electrically connected through a wiring line in the interposer substrate 310.

The upper wiring patterns 316 of the upper buildup portion UP may connect at least some of the second interposer pads 317. For example, the first semiconductor chip 320 and the second semiconductor chip 330 may be electrically connected through the upper buildup portion UP. Some of the second interposer pads 317 mounted on the first semiconductor chip 320 may be connected through the upper wiring patterns 316 to some of the second interposer pads 317 mounted on the second semiconductor chip 330. Hence, a chip-to-chip connection may be achieved between the first semiconductor chip 320 and the second semiconductor chip 330. As the first semiconductor chip 320 and the second semiconductor chip 330 may be connected through the upper buildup portion UP of the interposer substrate 310 that immediately underlies the first semiconductor chip 320 and the second semiconductor chip 330, a short length of electrical connection may be provided between the first semiconductor chip 320 and the second semiconductor chip 330, and a semiconductor package may have improved electrical properties.

A molding layer 340 may be provided on the interposer substrate 310. On the interposer substrate 310, the molding layer 340 may cover the first semiconductor chip 320 and the second semiconductor chip 330. The molding layer 340 may have the same width as that of the interposer substrate 310. For example, lateral surfaces of the molding layer 340 may be vertically aligned with lateral surfaces of the interposer substrate 310. The molding layer 340 may cover the bonding wires 326 and the top surfaces of the first semiconductor chip 320 and the second semiconductor chip 330. A flowable dielectric material may be cured to form the molding layer 340 and bury the bonding wires 326. The molding layer 340 may include a dielectric polymer material. For example, the molding layer 340 may include an epoxy molding compound (EMC).

The module structure MS may be connected to the first redistribution substrate 100. A direct bonding method may be used to mount the module structure MS on the first redistribution substrate 100. For example, the first interposer pads 314 of the module structure MS may be provided on a bottom surface of the interposer substrate 310. The interposer substrate 310 of the module structure MS may be in contact with the first redistribution substrate 100, and the first substrate wiring pattern 120 of the first redistribution substrate 100 may penetrate the uppermost first substrate dielectric pattern 110 to be coupled to the first interposer pads 314. Therefore, the module structure MS may be electrically connected through the first redistribution substrate 100 to the connection substrate 200 and the external terminals 150.

The present inventive concepts, however, are not limited thereto, and a bottom surface of the module structure MS may be spaced apart from the top surface of the first redistribution substrate 100. For example, the module structure MS may be connected to the first redistribution substrate 100 through a terminal, such as a micro-solder ball, separately provided on the first interposer pads 314. The following description will focus on FIG. 1.

A dielectric member 400 may be provided. The dielectric member 400 may be provided on the connection substrate 200. The dielectric member 400 may cover the connection substrate 200 and the module structure MS. The dielectric member 400 may be disposed in the opening OP of the connection substrate 200. The dielectric member 400 may be fill the opening OP of the connection substrate 200. For example, in the opening OP of the connection substrate 200, the dielectric member 400 may fill a gap between the connection substrate 200 and the module structure MS. In some embodiments, when the module structure MS and the first redistribution substrate 100 are spaced apart from each other, the dielectric member 400 may fill a space between the module structure MS and the first redistribution substrate 100.

The dielectric member 400 may cover the top surface of the connection substrate 200 and the top surface of the module structure MS. For example, the dielectric member 400 may surround the interposer substrate 310 and the molding layer 340, and may cover a top surface of the molding layer 340. In an embodiment, the dielectric member 400 may expose at least a portion of the top surface of the molding layer 340. The dielectric member 400 may include a different material from that of the molding layer 340. The dielectric member 400 may include a prepreg, a thermosetting film such as AJINOMOTO BUILD-UP FILM® (ABF), a glass epoxy laminate such as flame retardant 4 (FR-4), or bismaleimide triazine (BT). In an embodiment, the dielectric member 400 may include a dielectric polymer, such as polyimide (PI). In an embodiment, the dielectric member 400 may include a photo-imageable dielectric.

A second redistribution substrate 500 may be provided on the dielectric member 400. The second redistribution substrate 500 may include one or more second substrate wiring layers that are stacked on each other. Each of the second substrate wiring layers may include a second substrate dielectric pattern 510 and a second substrate wiring pattern 520 in the second substrate dielectric pattern 510. The second substrate wiring pattern 520 in a second substrate wiring layer may be electrically connected to the second substrate wiring pattern 520 in an adjacent second substrate wiring layer. The following will describe an example in which one second substrate wiring layer is used to explain a configuration of the second substrate dielectric pattern 510 and the second substrate wiring pattern 520.

The second substrate dielectric pattern 510 may include a polymer. For example, the second substrate dielectric pattern 510 may include a dielectric polymer or a photo-imageable dielectric (PID). For example, the photo-imageable dielectric may include at least one selected from photosensitive polyimide, polybenzoxazole (PBO), phenolic polymers, or benzocyclobutene polymers. In an embodiment, the second substrate dielectric pattern 510 may include a dielectric material. For example, the second substrate dielectric pattern 510 may include silicon oxide (SiO), silicon nitride (SiN), silicon oxynitride (SiON), or a dielectric polymer.

The second substrate wiring pattern 520 may be provided on the second substrate dielectric pattern 510. The second substrate wiring pattern 520 may horizontally extend on a top surface of the second substrate dielectric pattern 510. The second substrate wiring patterns 520 may protrude onto the top surface of the second substrate dielectric pattern 510. On the top surface of the second substrate dielectric pattern 510, the second substrate wiring pattern 520 may be covered with an overlying second substrate dielectric pattern 510. A lowermost second substrate wiring pattern 520 may be provided on a top surface of the dielectric member 400, and on the dielectric member 400, may be covered with an overlying second substrate dielectric pattern 510. The second substrate wiring pattern 520 may be a pad or line part of the second substrate wiring layer. In this sense, the second substrate wiring pattern 520 may be a component for horizontal redistribution in the second redistribution substrate 500. The second substrate wiring pattern 520 may include a conductive material. For example, the second substrate wiring pattern 520 may include copper (Cu). The second substrate wiring pattern 520 of an uppermost second substrate wiring layer may be exposed on a top surface of the second redistribution substrate 500, and may serve as a pad on which an external package or an electronic apparatus is mounted.

The second substrate wiring pattern 520 may have a damascene structure. For example, the second substrate wiring pattern 520 may have a via that protrudes onto a bottom surface thereof. The via may be a component for vertically connecting the second substrate wiring patterns 520 of the second substrate wiring layers that are vertically adjacent to each other. For example, the via may extend from the bottom surface of the second substrate wiring pattern 520, and may penetrate the second substrate dielectric pattern 510 to be coupled to the second substrate wiring pattern 520 of an underlying second substrate wiring layer. In an embodiment, the via may be a component for connecting the lowermost second substrate wiring pattern 520 to the connection substrate 200. For example, the via may extend from the bottom surface of the second substrate wiring pattern 520, and may penetrate the dielectric member 400 to be coupled to the upper pads 222 of the connection substrate 200. In this configuration, an upper portion of the second substrate wiring pattern 520 positioned on the top surface of the second substrate dielectric pattern 510 may be a head part used as a horizontal line or pad, and the via of the second substrate wiring pattern 520 may be a tail part. The second substrate wiring pattern 520 may have a T shape.

Some of the vias of the second substrate wiring patterns 520 may be connected to the first semiconductor chip 320. In this description, first vias 522 may be defined to indicate the vias connected to the first semiconductor chip 320. A shape and arrangement of the first vias 522 will be discussed in detail below based on a first via 522.

Referring to FIG. 2, a first vertical hole VH1 may be provided. On the first semiconductor chip 320, the first vertical hole VH1 may vertically penetrate the dielectric member 400 and the molding layer 340. The first vertical hole VH1 may expose the first semiconductor chip 320. A bottom surface of the first vertical hole VH1 may be the top surface of the first semiconductor chip 320. The first vertical hole VH1 may be covered with at least one of the second substrate wiring patterns 520. For example, a top surface of the first vertical hole VH1 may be a bottom surface of a second substrate wiring pattern of the second substrate wiring patterns 520. When viewed in plan, the first vertical hole VH1 may be positioned between the first chip pads 324. For example, the first chip pads 324 may be provided on an edge region of the top surface of the first semiconductor chip 320, and the first vertical hole VH1 may be provided on a central region of the top surface of the first semiconductor chip 320. An inner lateral surface of the first vertical hole VH1 may be inclined to the top surface of the first semiconductor chip 320. The first vertical hole VH1 may have a width that decreases with decreasing distance from the interposer substrate 310. For example, the first vertical hole VH1 may have a shape that is tapered toward the interposer substrate 310.

The first vertical hole VH1 may include a first hole VH1a that penetrates the molding layer 340 and a second hole VH1b that penetrates the dielectric member 400. The first hole VH1a and the second hole VH1b may have inner lateral surfaces that are inclined to the top surface of the first semiconductor chip 320. The first hole VH1a may have a width W1 less than a width W2 of the second hole VH1b. The inner lateral surface of the first hole VH1a may be coplanar with the inner lateral surface of the second hole VH1b. For example, the first hole VH1a and the second hole VH1b may be vertically connected to form a hole or the first vertical hole VH1. In the molding layer 340 and the dielectric member 400, the first vertical hole VH1 may have a width that is uniformly changed in accordance with distance from the interposer substrate 310. In the molding layer 340 and the dielectric member 400, the inner lateral surface of the first vertical hole VH1 may be a continuous surface.

A first via 522 may be provided in the first vertical hole VH1. The first via 522 may be disposed in the first vertical hole VH1. The first via 522 may fill the first vertical hole VH1. The first via 522 may be in contact with the inner lateral surface of the first hole VH1a and the inner lateral surface of the second hole VH1b. For example, the first via 522 may have a width that decreases with decreasing distance from the interposer substrate 310. In the molding layer 340 and the dielectric member 400, the width of the first via 522 may be uniformly changed in accordance with distance from the interposer substrate 310. For example, the first via 522 may have a shape that is tapered toward the interposer substrate 310. In an embodiment, the first via 522 may have a wedge shape which is directed toward the interposer substrate 310 and whose end is flat. The first via 522 may connect the top surface of the first semiconductor chip 320 to a second substrate wiring pattern of the second substrate wiring patterns 520. In the following description, a first via connection pattern 524 may be defined to indicate a second substrate wiring pattern of the second substrate wiring patterns 520 that is coupled to the first via 522. For example, the first via 522 may be a portion of the first via connection pattern 524, which portion extends from the first via connection pattern 524 toward the first semiconductor chip 320. The first via connection pattern 524 may be positioned on the first semiconductor chip 320. The first via connection pattern 524 may be electrically insulated from the module structure MS. For example, the first via connection pattern 524 may be electrically floated from other second substrate wiring patterns 520 electrically connected to the connection substrate 200. The present inventive concepts, however, are not limited thereto. The first via connection pattern 524 may be electrically connected to the connection substrate 200. For example, the first via connection pattern 524 may be electrically connected to a ground circuit. When viewed in plan, the first via connection pattern 524 may have a plate shape, a grid shape, a linear pattern, or any other suitable patterns. The present inventive concepts are, however, not limited thereto, and the first via connection pattern 524 may have variously shapes.

A plurality of first vias 522 may be provided. For example, a plurality of first vias 522 may be connected to a first via connection pattern 524. The first vias 522 may be disposed spaced apart from each other. A planar arrangement of the first vias 522 may conform to a grid arrangement or a honeycomb arrangement. The present inventive concepts, however, are not limited thereto. According to some embodiments, a plurality of first via connection patterns 524 may be provided. For example, the first via connection patterns 524 may be disposed horizontally spaced apart from each other on the first semiconductor chip 320, and at least one first via 522 may be connected to each of the first via connection patterns 524.

According to some embodiments of the present inventive concepts, the first vias 522 may connect the first semiconductor chip 320 to the first via connection pattern 524 of the second redistribution substrate 500. For example, the first vias 522 may be in contact with the top surface of the first semiconductor chip 320. The first vias 522 may be used as heat paths for conducting heat generated from the first semiconductor chip 320. For example, the first vias 522 may transfer the heat received from the first semiconductor chip 320 to the first via connection pattern 524, and the heat may be discharged through the first via connection pattern 524 and the second substrate wiring patterns 520 to an upside of the second redistribution substrate 500. Therefore, a semiconductor package may increase in thermal radiation efficiency.

In addition, as the first via connection pattern 524 downwardly covers the first semiconductor chip 320, the first via connection pattern 524 may shield electromagnetic waves that are directed toward the first semiconductor chip 320 from an outside of the first via connection pattern 524 or electromagnetic waves that are outwardly directed from the first semiconductor chip 320. It may thus be possible to provide a semiconductor package with improved protection from electromagnetic interference and improved electrical properties.

FIG. 2 depicts that the first via 522 has a shape that is tapered toward the interposer substrate 310, but the present inventive concepts are not limited thereto.

Referring to FIG. 3, the first vertical hole VH1 may include a first hole VH1a that penetrates the molding layer 340 and a second hole VH1b that penetrates the dielectric member 400. The first hole VH1a and the second hole VH1b may have inner lateral surfaces that are inclined to each other and may form an inner surface of the first vertical hole VH1 having a bend. For example, the inner lateral surface of the first hole VH1a may be inclined to the top surface of the first semiconductor chip 320 at a first angle, and the inner lateral surface of the second hole VH1b may be inclined to the top surface of the first semiconductor chip 320 at a second angle. For example, the inner lateral surface of the second hole VH1b may be perpendicular to the top surface of the first semiconductor chip 320. In this case, the width W1 of the first hole VH1a may increase with increasing distance from the interposer substrate 310. The first hole VH1a may have a shape that is tapered toward the interposer substrate 310. A width W1 of the first hole VH1a and a width W2 of the second hole VH1b may be the same at a boundary between the first hole VH1a and the second hole VH1b. The width W2 of the second hole VH1b may be constant regardless of distance from the interposer substrate 310. For example, the second hole VH1b may have a pillar shape whose width W2 is constant.

A first via 522 may be provided in the first vertical hole VH1. The first via 522 may be disposed in the first vertical hole VH1. The first via 522 may fill the first vertical hole VH1. The first via 522 may be in contact with the inner lateral surface of the first hole VH1a and the inner lateral surface of the second hole VH1b. A width of the first via 522 in the molding layer 340 may decrease with decreasing distance from the interposer substrate 310, and a width of the first via 522 in the dielectric member 400 may be constant regardless of distance from the first semiconductor chip 320. For example, the first via 522 may have a tapered shape in the molding layer 340 and a pillar shape whose width is constant in the dielectric member 400.

FIG. 2 and FIG. 3 depict that the first hole VH1a and the second hole VH1b may be vertically connected to form a first vertical hole VH1, but the present inventive concepts are not limited thereto.

Referring to FIG. 4, a first hole VH1a may be provided which vertically penetrates the molding layer 340, and a second hole VH1b may be provided which vertically penetrates the dielectric member 400. The first hole VH1a and the second hole VH1b may vertically overlap each other. For example, the second hole VH1b may be disposed within the first hole VH1a. The first hole VH1a may have a width W1 and a planar shape greater than a width W2 and a planar shape of the second hole VH1b. At an arbitrary vertical level, the width W1 of the first hole VH1a may be greater than the width W2 of the second hole VH1b. For example, the first hole VH1a may extend from the top surface of the molding layer 340 to the top surface of the first semiconductor chip 320. The dielectric member 400 may cover the molding layer 340, and a portion of the dielectric member 400 may extend into the first hole VH1a. The second hole VH1b may extend from the top surface of the dielectric member 400 to the top surface of the first semiconductor chip 320. According to an embodiment, the second hole VH1b may run across an inner region of the first hole VH1a. When viewed downwardly from the dielectric member 400, the second hole VH1b may expose the top surface of the first semiconductor chip 320. An inner lateral surface of the first hole VH1a may be inclined to the top surface of the first semiconductor chip 320. The width W1 of the first hole VH1a may decrease with decreasing distance from the interposer substrate 310. The first hole VH1a may have a shape that is tapered toward the interposer substrate 310. An inner lateral surface of the second hole VH1b may be perpendicular to the top surface of the first semiconductor chip 320. For example, the second hole VH1b may have a pillar shape whose width W2 may be constant.

A first via 522 may be provided in the second hole VH1b. For example, the second hole VH1b may correspond to a vertical hole in which the first via 522 is provided. The first via 522 may be disposed in the second hole VH1b. The first via 522 may fill the second hole VH1b. The first via 522 may be in contact with an inner lateral surface of the second hole VH1b, and the dielectric member 400 may separate the first via 522 from the molding layer 340 or an inner lateral surface of the first hole VH1a. The dielectric member 400 may extend from the molding layer 340 into the first hole VH1a, and may extend between the first via 522 and the inner lateral surface of the first hole VH1a. The portion of the dielectric member 400 may have a bottom surface located at the same level as that of a bottom surface of the first via 522. The first via 522 may have a width that is uniform regardless of distance from the first semiconductor chip 320. For example, the first via 522 may have a pillar shape whose width is constant.

In embodiments that follow, components the same as those discussed with reference to FIGS. 1 to 4 are allocated the same reference numerals thereto, and a repetitive explanation thereof may be omitted or abridged for convenience of description.

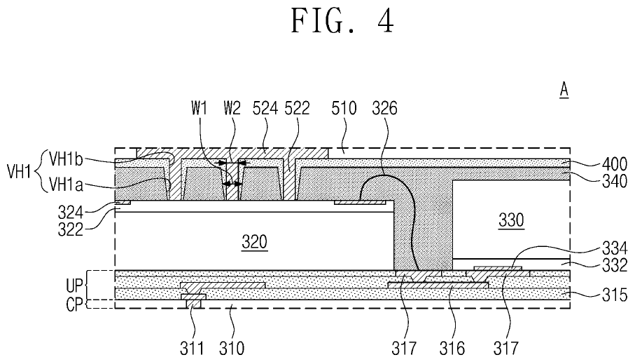

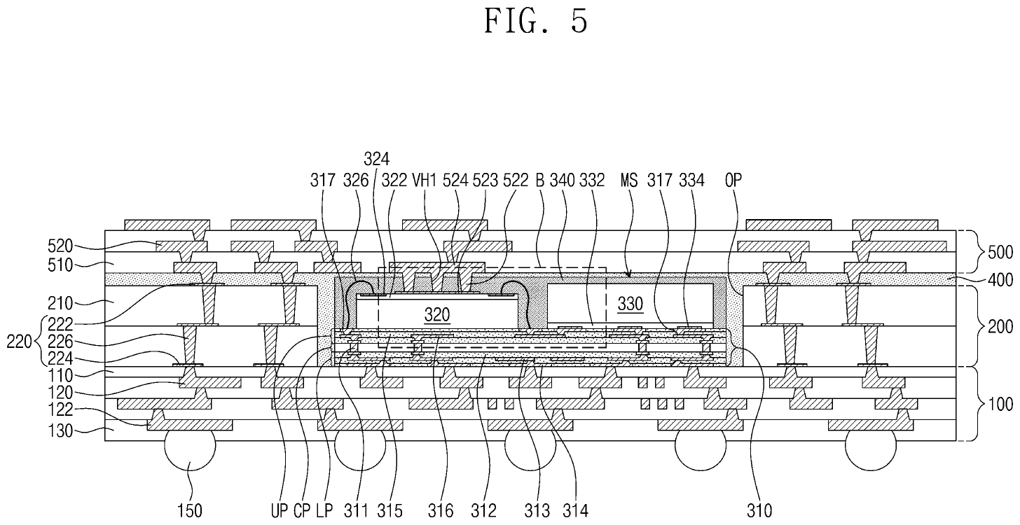

FIG. 5 illustrates a cross-sectional view showing a semiconductor package according to some embodiments of the present inventive concepts. FIG. 6 illustrates an enlarged view showing section B of FIG. 5.

Referring to FIG. 5 and FIG. 6, the module structure MS may further include a first thermal radiation member 523. The first thermal radiation member 523 may be disposed on a top surface of the first semiconductor chip 320. The first thermal radiation member 523 may be in contact with the top surface of the first semiconductor chip 320. When viewed in plan, the first thermal radiation member 523 may be positioned between the first chip pads 324 of the first semiconductor chip 320. When viewed in plan, the first thermal radiation member 523 may have a plate shape, a grid shape, a linear pattern, or any other suitable pattern. The present inventive concepts are, however, not limited thereto, and the first thermal radiation member 523 may have various planar shapes. The first thermal radiation member 523 may include a material whose thermal conductance is high. For example, the first thermal radiation member 523 may include a metallic material.

First vertical holes VH1 may be provided. On the first semiconductor chip 320, the first vertical holes VH1 may vertically penetrate the dielectric member 400 and the molding layer 340. The first vertical holes VH1 may expose the first thermal radiation member 523. The first vertical holes VH1 may have a shape the same as or similar to that discussed with reference to FIG. 2, FIG. 3, and FIG. 4.

First vias 522 may be provided in the first vertical holes VH1. The first vias 522 may correspondingly fill the first vertical holes VH1. The first vias 522 may connect a top surface of the first thermal radiation member 523 to the first via connection pattern 524. The first via connection pattern 524 may be positioned on the first thermal radiation member 523.

According to some embodiments of the present inventive concepts, the first thermal radiation member 523 may be provided on the top surface of the first semiconductor chip 320. In accordance with a shape of the first thermal radiation member 523, a contact area may be provided between the first semiconductor chip 320 and the first thermal radiation member 523. The contact area, which may be provided by the first thermal radiation member 523, may be large. The first thermal radiation member 523 may receive heat from the first semiconductor chip 320, and the heat may be outwardly discharged from a semiconductor package through the first thermal radiation member 523, the first vias 522, and the first via connection pattern 524. Accordingly, the semiconductor package may have an increased thermal radiation efficiency.

FIGS. 1 to 6 depict that the first vias 522 are provided on the first semiconductor chip 320, which may be wire-bond mounted on the interposer substrate 310, but the present inventive concepts are not limited thereto.

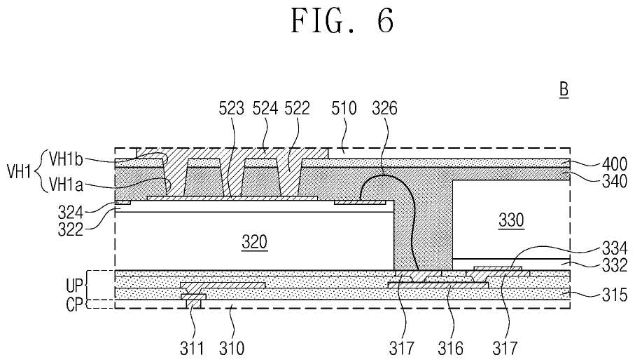

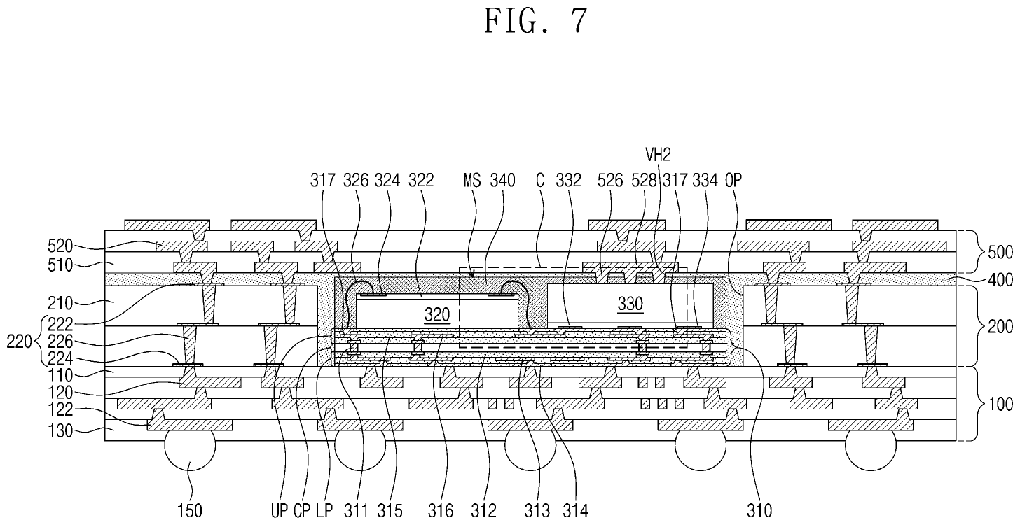

FIG. 7 illustrates a cross-sectional view showing a semiconductor package according to some embodiments of the present inventive concepts. FIG. 8, FIG. 9, and FIG. 10 illustrate enlarged views showing section C of FIG. 7.

Referring to FIG. 7 and FIG. 8, some of the vias of the second substrate wiring patterns 520 may be connected to the second semiconductor chip 330. In this description, second vias 526 may be defined to indicate the vias connected to the second semiconductor chip 330. A shape and arrangement of the second vias 526 will be discussed in detail below based on a second via 526.

Referring to FIG. 8, a second vertical hole VH2 may be provided. On the second semiconductor chip 330, the second vertical hole VH2 may vertically penetrate the dielectric member 400 and the molding layer 340. The second vertical hole VH2 may expose the second semiconductor chip 330. A bottom surface of the second vertical hole VH2 may be the top surface of the second semiconductor chip 330. At least one of the second substrate wiring patterns 520 may be disposed on the second vertical hole VH2. For example, a top surface of the second vertical hole VH2 may be a bottom surface of a second substrate wiring pattern of the second substrate wiring patterns 520. An inner lateral surface of the second vertical hole VH2 may be inclined to the top surface of the second semiconductor chip 330. The second vertical hole VH2 may have a width that decreases with decreasing distance from the interposer substrate 310. For example, the second vertical hole VH2 may a shape that is tapered toward the interposer substrate 310.

The second vertical hole VH2 may include a third hole VH2a that penetrates the molding layer 340 and a fourth hole VH2b that penetrates the dielectric member 400. The third hole VH2a and the fourth hole VH2b may have inner lateral surfaces that are inclined to the top surface of the second semiconductor chip 330. The third hole VH2a may have a width W3 less than a width W4 of the fourth hole VH2b. The inner lateral surface of the third hole VH2a may be coplanar with the inner lateral surface of the fourth hole VH2b. For example, the third hole VH2a and the fourth hole VH2b may be vertically connected to form the second vertical hole VH2. In the molding layer 340 and the dielectric member 400, the second vertical hole VH2 may have a width that is uniformly changed in accordance with distance from the interposer substrate 310. In the molding layer 340 and the dielectric member 400, the inner lateral surface of the second vertical hole VH2 may be a continuous surface.

A second via 526 may be provided in the second vertical hole VH2. The second via 526 may fill the second vertical hole VH2. The second via 526 may have a width that decreases with decreasing distance from the interposer substrate 310. In the molding layer 340 and the dielectric member 400, the width of the second via 526 may be uniformly changed in accordance with distance from the interposer substrate 310. For example, the second via 526 may have a shape that is tapered toward the interposer substrate 310. The second via 526 may connect the top surface of the second semiconductor chip 330 to a second substrate wiring pattern of the second substrate wiring patterns 520. In the following description, a second via connection pattern 528 may be defined to indicate a second substrate wiring pattern of the second substrate wiring patterns 520 that is coupled to the second via 526. For example, the second via 526 may be a portion of the second via connection pattern 528, which portion extends from the second via connection pattern 528 toward the second semiconductor chip 330. The second via connection pattern 528 may be positioned on the second semiconductor chip 330. The second via connection pattern 528 may be electrically insulated from the module structure MS. When viewed in plan, the second via connection pattern 528 may have a plate shape, a grid shape, a linear pattern, or any other suitable patterns.

In an embodiment, a plurality of second vias 526 may be provided. For example, a plurality of second vias 526 may be connected to one second via connection pattern 528. The second vias 526 may be disposed spaced apart from each other. According to some embodiments, a plurality of second via connection patterns 528 may be provided.

According to some embodiments of the present inventive concepts, the second vias 526 may connect the second semiconductor chip 330 to the second via connection pattern 528 of the second redistribution substrate 500. The second vias 526 may be used as heat paths for conducting heat generated from the second semiconductor chip 330. For example, the second vias 526 may conduct the heat received from the second semiconductor chip 330 to the second via connection pattern 528, and the heat may be discharged through the second via connection pattern 528 and the second substrate wiring patterns 520 to an upside of the second redistribution substrate 500. According to an embodiment, a semiconductor package may have improved thermal radiation efficiency. In addition, as the second via connection pattern 528 downwardly covers the second semiconductor chip 330, the second via connection pattern 528 may shield the second semiconductor chip 330 from electromagnetic waves that are directed toward the second semiconductor chip 330 from an outside of the second via connection pattern 528 or electromagnetic waves that are outwardly directed from the second semiconductor chip 330. It may thus be possible to provide a semiconductor package with improved protection from electromagnetic interference and improved electrical properties.

According to some embodiments, as shown in FIG. 9, the third hole VH2a and the fourth hole VH2b may have inner lateral surfaces that are inclined to each other and may form an inner surface of the second via 526 having a bend. For example, the inner lateral surface of the third hole VH2a may be inclined to the top surface of the second semiconductor chip 330 at a first angle, and the inner lateral surface of the fourth hole VH2b may be inclined to the top surface of the second semiconductor chip 330 at a second angle. For example, the inner lateral surface of the fourth hole VH2b may be perpendicular to the top surface of the second semiconductor chip 330. The width W3 of the third hole VH2a and the width W4 of the fourth hole VH2b may be the same at a boundary between the third hole VH2a and the fourth hole VH2b. A second via 526 may be provided in the second vertical hole VH2. The second via 526 may fill the second vertical hole VH2. A width of the second via 526 in the molding layer 340 may decrease with decreasing distance from the interposer substrate 310, and a width of the second via 526 in the dielectric member 400 may be constant regardless of distance from the second semiconductor chip 330. For example, the second via 526 may have a tapered shape in the molding layer 340 and a pillar shape whose width is constant in the dielectric member 400.

According to some embodiments, as shown in FIG. 10, a third hole VH2a may be provided which vertically penetrates the molding layer 340, and a fourth hole VH2b may be provided which vertically penetrates the dielectric member 400. The third hole VH2a and the fourth hole VH2b may vertically overlap each other. At an arbitrary vertical level, the width W3 of the third hole VH2a may be greater than the width W4 of the fourth hole VH2b. The dielectric member 400 may cover the molding layer 340, and a portion of the dielectric member 400 may extend into the third hole VH2a. The fourth hole VH2b may extend from the top surface of the dielectric member 400 to the top surface of the second semiconductor chip 330, while running across an inner region of the third hole VH2a. When viewed downwardly from the dielectric member 400, the fourth hole VH2b may expose the top surface of the second semiconductor chip 330. An inner lateral surface of the third hole VH2a may be inclined to the top surface of the second semiconductor chip 330. An inner lateral surface of the fourth hole VH2b may be perpendicular to the top surface of the second semiconductor chip 330.

A second via 526 may be provided in the fourth hole VH2b. For example, the fourth hole VH2b may correspond to a vertical hole in which the second via 526 is provided. The dielectric member 400 may separate the second via 526 from the molding layer 340 or the inner lateral surface of the third hole VH2a. For example, the dielectric member 400 may extend between the second via 526 and the inner lateral surface of the third hole VH2a. The portion of the dielectric member 400 may have a bottom surface located at the same level as that of a bottom surface of the second via 526. The second via 526 may have a width that is uniform regardless of distance from the second semiconductor chip 330.

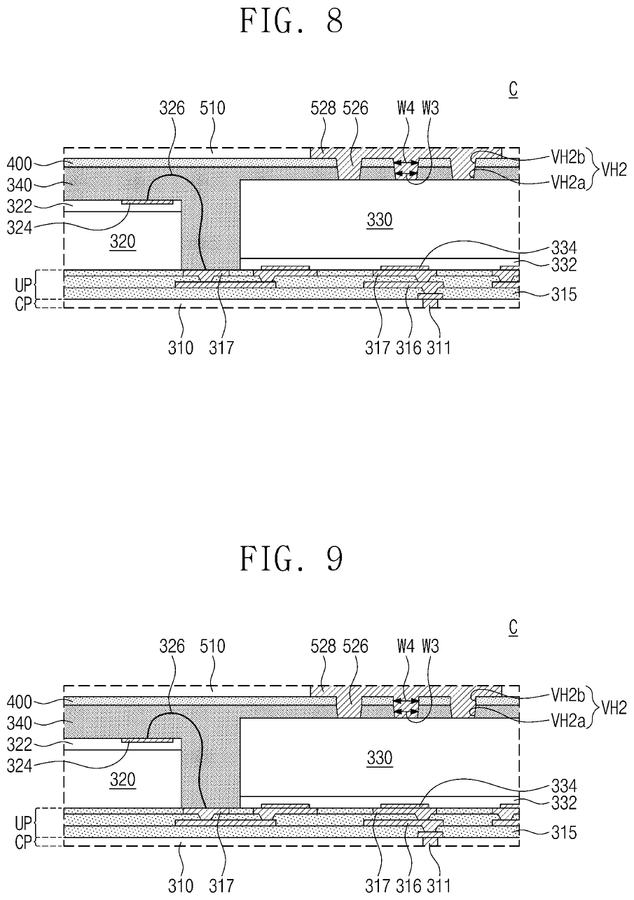

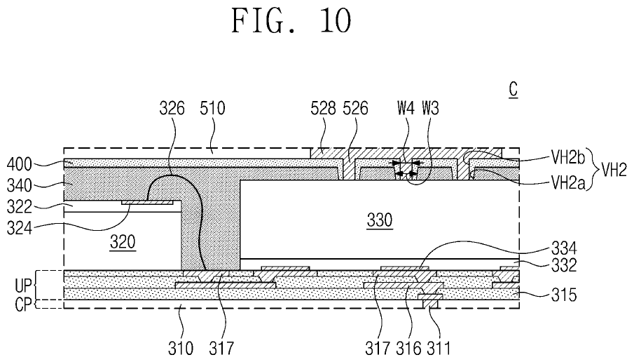

FIG. 11 illustrates a cross-sectional view showing a semiconductor package according to some embodiments of the present inventive concepts. FIG. 12 illustrates an enlarged view showing section D of FIG. 11.

Referring to FIG. 11 and FIG. 12, the module structure MS may further include a second thermal radiation member 527. The second thermal radiation member 527 may be disposed on a top surface of the second semiconductor chip 330. The second thermal radiation member 527 may be in contact with the top surface of the second semiconductor chip 330. FIG. 11 and FIG. 12 depict that the second thermal radiation member 527 covers an entirety of the top surface of the second semiconductor chip 330, but the present inventive concepts are not limited thereto. When viewed in plan, the second thermal radiation member 527 may have a plate shape, a grid shape, a linear pattern, or any other suitable patterns. The second thermal radiation member 527 may include a material whose thermal conductance is high. For example, the second thermal radiation member 527 may include a metallic material.

Second vertical holes VH2 may be provided. On the second semiconductor chip 330, the second vertical holes VH2 may vertically penetrate the dielectric member 400 and the molding layer 340. The second vertical holes VH2 may expose the second thermal radiation member 527. A shape of the second thermal radiation member 527 may be the same as or similar to that discussed with reference to FIGS. 8 to 10.

Second vias 526 may be provided in the second vertical holes VH2. The second vias 526 may connect a top surface of the second thermal radiation member 527 to the second via connection pattern 528. The second via connection pattern 528 may be positioned on the second thermal radiation member 527.

According to some embodiments of the present inventive concepts, the second thermal radiation member 527 may be provided on the top surface of the second semiconductor chip 330. The second thermal radiation member 527 may receive heat from the second semiconductor chip 330, and the heat may be outwardly discharged from a semiconductor package through the second thermal radiation member 527, the second vias 526, and the second via connection pattern 528. Accordingly, the semiconductor package may increase in thermal radiation efficiency.

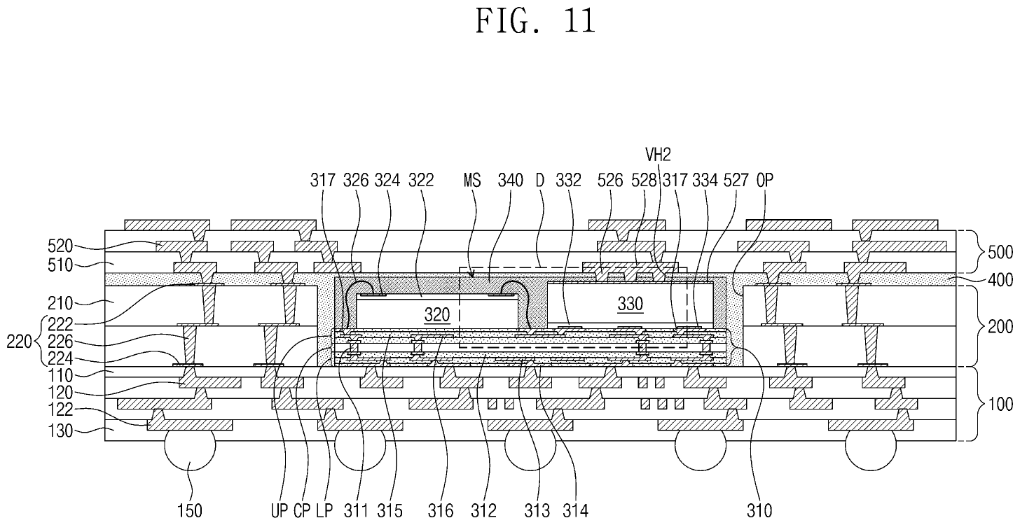

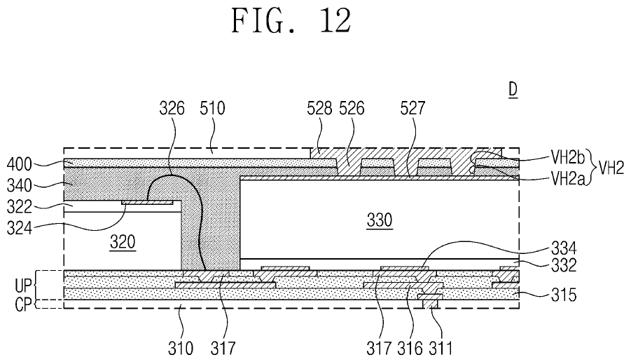

FIG. 13 illustrates a cross-sectional view showing a semiconductor package according to some embodiments of the present inventive concepts. FIG. 14 illustrates an enlarged view showing section E of FIG. 13.

Referring to FIG. 13 and FIG. 14, a semiconductor package may include the first vias 522 discussed with reference to FIGS. 1 to 6, and the second vias 526 discussed with reference to FIGS. 7 to 12.

The module structure MS may include the first vias 522 that are disposed on the first semiconductor chip 320 and connect a top surface of the first semiconductor chip 320 to the first via connection pattern 524, and may also include the second vias 526 that are disposed on a top surface of the second semiconductor chip 330 to the second via connection pattern 528. The first vias 522 may be the same as or similar to the first vias 522 discussed with reference to FIGS. 1 to 6, and the second vias 526 may be the same as or similar to the second vias 526 discussed with reference to FIGS. 7 to 12.

The module structure MS may further include a first thermal radiation member and a second thermal radiation member 527. The first thermal radiation member 523 may be disposed on the first semiconductor chip 320 to contact the top surface of the first semiconductor chip 320.

The first vias 522 may vertically penetrate the dielectric member 400 and the molding layer 340 to be connected to the first thermal radiation member 523. The second thermal radiation member 527 may be disposed on the second semiconductor chip 330 to contact the top surface of the second semiconductor chip 330. The second vias 526 may vertically penetrate the dielectric member 400 and the molding layer 340 to be connected to the second thermal radiation member 527. The first thermal radiation member 523 and the second thermal radiation member 527 may be omitted. In this case, the first vias 522 and the second vias 526 may be in direct contact with the top surface of the first semiconductor chip 320 and the top surface of the second semiconductor chip 330, respectively.

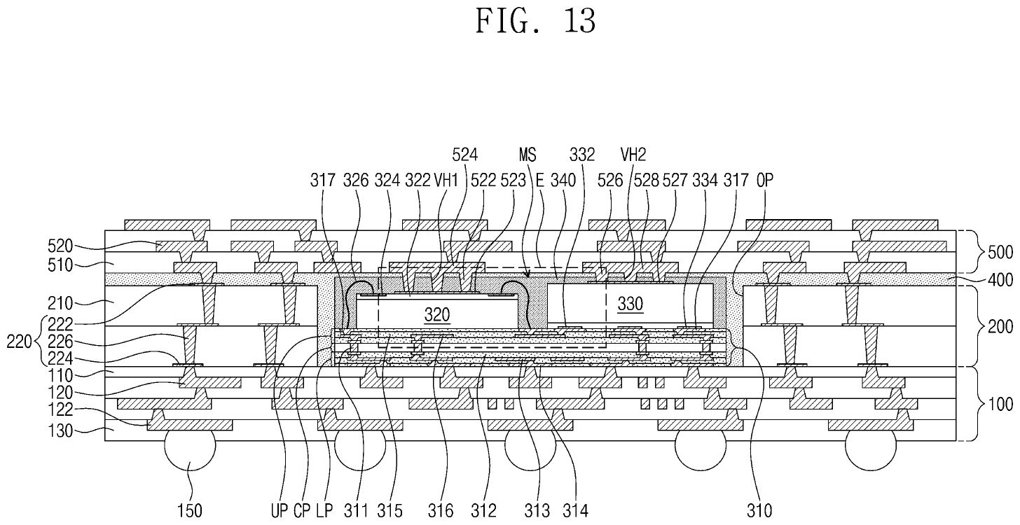

FIG. 15 illustrates a cross-sectional view showing a semiconductor package according to some embodiments of the present inventive concepts.

Referring to FIG. 15, the module structure MS may have another first semiconductor chip 320 instead of the second semiconductor chip 330. For example, the module structure MS may include a plurality of first semiconductor chips 320 mounted on the interposer substrate 310. The first semiconductor chips 320 may only means chips wire-bond mounted on the interposer substrate 310, and the first semiconductor chips 320 may not be exactly the same as each other.

The first vias 522 may be provided on each of the first semiconductor chips 320. The first vias 522 may connect the first via connection patterns 524 to either top surfaces of the first semiconductor chips 320 or the first thermal radiation members 523 provided on the first semiconductor chips 320.

Although not shown, according to some embodiments, the module structure MS may have another second semiconductor chip 330 instead of the first semiconductor chip 320. For example, the module structure MS may include a plurality of second semiconductor chips 330 mounted on the interposer substrate 310. The second semiconductor chips 330 may only means chips direct-bond or flip-chip mounted on the interposer substrate 310, and the second semiconductor chips 330 may not be exactly the same as each other.

The second vias 526 may be provided on each of the second semiconductor chips 330. The second vias 526 may connect the second via connection patterns 528 to either top surfaces of the second semiconductor chips 330 or the second thermal radiation members 527 provided on the second semiconductor chips 330.

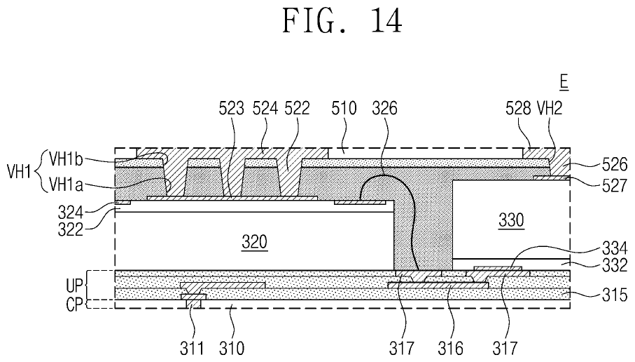

FIG. 16 illustrates a cross-sectional view showing a semiconductor package according to some embodiments of the present inventive concepts.

Referring to FIG. 16, the first semiconductor chip 320 may be disposed on the second semiconductor chip 330. For example, the second semiconductor chip 330 may be direct-bond mounted on the interposer substrate 310. A rear surface of the second semiconductor chip 330 may be disposed as a top surface of the second semiconductor chip 330. The first semiconductor chip 320 may be disposed on the second semiconductor chip 330. For example, a rear surface of the first semiconductor chip 320 may be attached to the top surface of the second semiconductor chip 330. A front surface of the first semiconductor chip 320 may be disposed as a top surface of the first semiconductor chip 320. The second semiconductor chip 330 may be mounted on the interposer substrate 310 through the bonding wires 326. The bonding wires 326 may extend from the top surface of the second semiconductor chip 330 to the interposer substrate 310. One chip stack may be constituted by the first semiconductor chip 320 and the second semiconductor chip 330 that are vertically stacked. FIG. 16 depicts that two chip stacks are provided on the interposer substrate 310, but the present inventive concepts are not limited thereto, and a semiconductor package may include one or more chip stacks.

The first vias 522 may be provided on each of the chip stacks. The first vias 522 may connect the first via connection patterns 524 to top surfaces of the chip stacks. For example, the first vias 522 may connect the first via connection patterns 524 to top surfaces of the first semiconductor chips 320. In an embodiment, the first vias 522 may connect the first via connection patterns 524 to the first thermal radiation members 523 provided on the chip stacks.

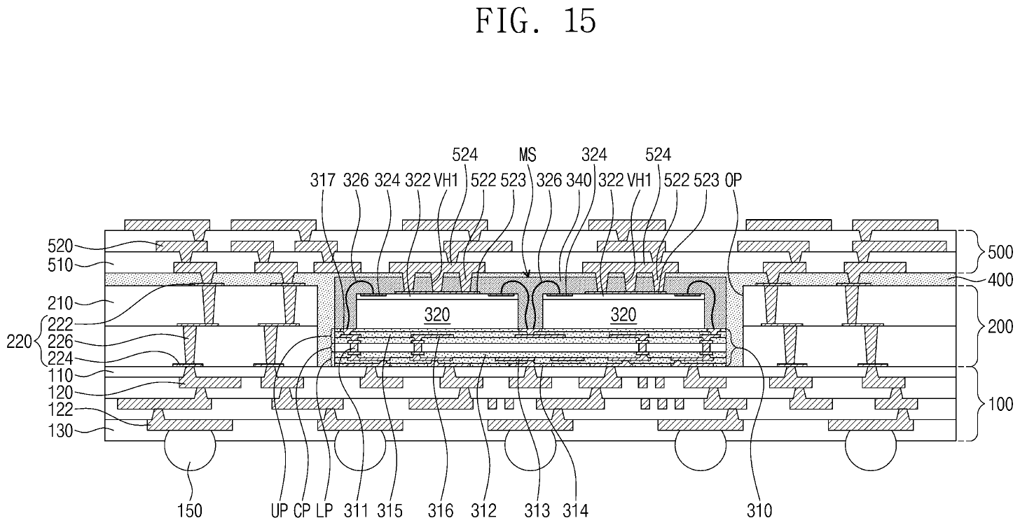

FIGS. 17 to 24 illustrate cross-sectional views showing a method of fabricating a semiconductor package according to some embodiments of the present inventive concepts.

Referring to FIG. 17, a core portion CP may be provided. Vertical connection terminals 311 may be formed in the core portion CP. For example, the vertical connection terminals 311 may be formed by forming holes that penetrate the core portion CP, and forming a conductive material in the holes. The conductive material may fill the holes.

A lower buildup portion LP may be formed on the core portion CP. For example, a dielectric layer may be formed on a surface of the core portion CP, and the dielectric layer may be patterned to form a lower dielectric pattern 312. A conductive layer may be formed on the lower dielectric pattern 312, and the conductive layer may be patterned to form a lower wiring pattern 313. The process for forming the lower dielectric pattern 312 and the lower wiring pattern 313 may be repeatedly performed. A plurality of lower dielectric patterns 312 and a plurality of lower wiring patterns 313 may constitute the lower buildup portion LP discussed with reference to FIG. 1.

In an embodiment, the lower buildup portion LP may be formed on a top surface of the core portion CP and a resultant structure may be turned upside down. Therefore, the lower buildup portion LP may be disposed below the core portion CP.

An upper buildup portion UP may be formed on the core portion CP. For example, a dielectric layer may be formed on a surface of the core portion CP, and the dielectric layer may be patterned to form an upper dielectric pattern 315. The upper dielectric pattern 315 may be formed on a surface of the core portion CP that is opposite to lower buildup portion LP. A conductive layer may be formed on the upper dielectric pattern 315, and the conductive layer may be patterned to form one upper wiring pattern 316. The process for forming the upper dielectric pattern 315 and the upper wiring pattern 316 may be repeatedly performed. A plurality of upper dielectric patterns 315 and a plurality of upper wiring patterns 316 may constitute the upper buildup portion UP discussed with reference to FIG. 1. An interposer substrate 310 may include the core portion CP, the upper buildup portion UP, and the lower buildup portion LP.

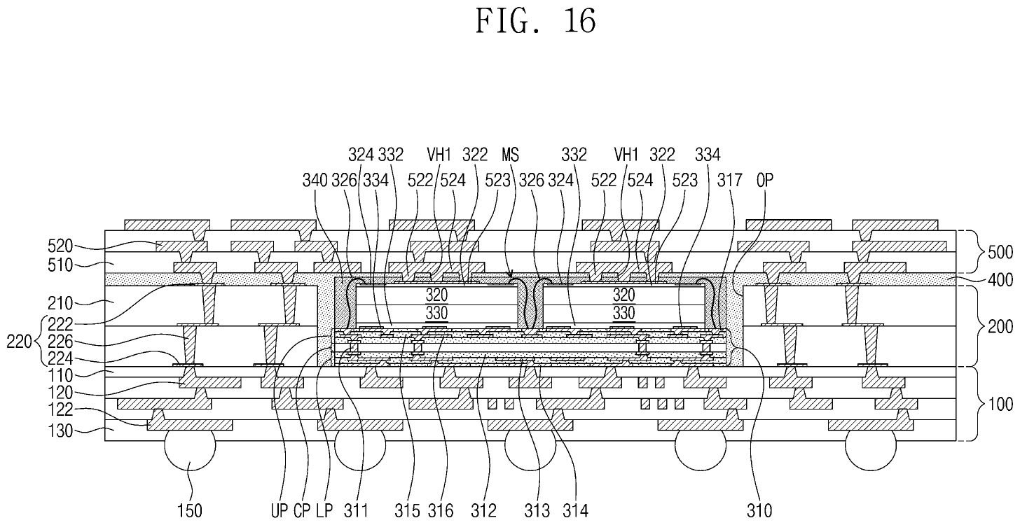

Referring to FIG. 18, a first semiconductor chip 320 and a second semiconductor chip 330 may be mounted on the interposer substrate 310. For example, the first semiconductor chip 320 and a second semiconductor chip 330 may be mounted on the upper buildup portion UP of the interposer substrate 310. The first semiconductor chip 320 and the second semiconductor chip 330 may be respectively substantially the same as or similar to the first semiconductor chip 320 and the second semiconductor chip 330 discussed with reference to FIGS. 1 to 16. For example, each of the first semiconductor chips 320 may include a first circuit layer 322 and first chip pads 324. Each of the second semiconductor chips 330 may include a second circuit layer 332 and second chip pads 334.

The first semiconductor chip 320 may be disposed or attached in a face-up state on or to the interposer substrate 310. Bonding wires 326 may be used to connect the first chip pads 324 of the first semiconductor chip 320 to second interposer pads 317.

The second semiconductor chip 330 may be disposed in a face-down state on the interposer substrate 310. The second chip pads 334 of the second semiconductor chip 330 may be aligned with the second interposer pad 317. An annealing process may be performed on the second chip pads 334 and the second interposer pads 317. The annealing process may bond the second chip pads 334 to the second interposer pads 317.

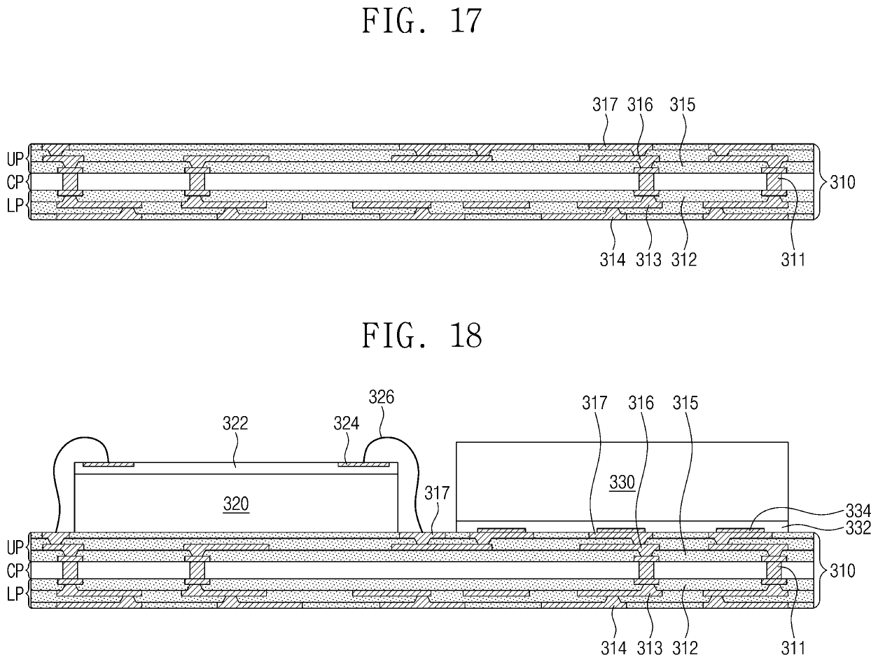

Referring to FIG. 19, a molding layer 340 may be formed on the upper buildup portion UP. For example, a dielectric material may be disposed on a top surface of the upper buildup portion UP and may surround the first semiconductor chip 320 and the second semiconductor chip 330. The dielectric material may be cured to form the molding layer 340. As the first semiconductor chip 320 includes the bonding wire 326, the dielectric material may include a material whose fluidity is high in a coating process. For example, the dielectric material may include an epoxy molding compound (EMC).

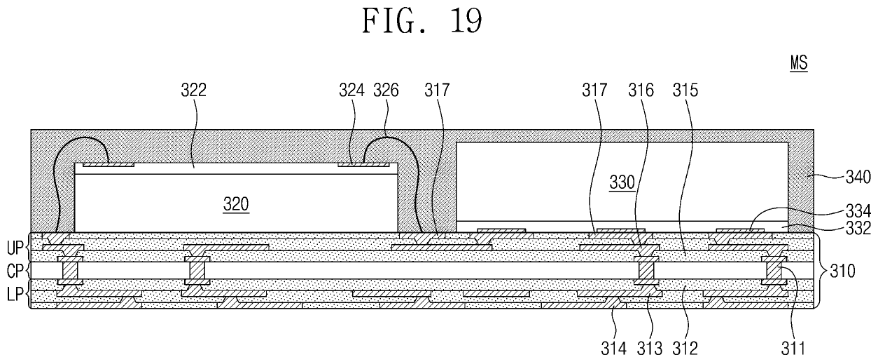

Referring to FIG. 20, a connection substrate 200 may be provided. The connection substrate 200 may be the same as or similar to the connection substrate 200 discussed with reference to FIGS. 1 to 12. For example, the connection substrate 200 may include a base layer 210 and a conductive member 220. The conductive member 220 may include upper pads 222, lower pads 224, and vias 226.

A carrier substrate 900 may be attached to a bottom surface of the connection substrate 200. The carrier substrate 900 may be a dielectric substrate including glass or polymer, or may be a conductive substrate including metal. The carrier substrate 900 may be attached to the lower pads 224 and the base layer 210 of the connection substrate 200 through an adhesive member (not shown) provided on a top surface of the carrier substrate 900. For example, the adhesive member (not shown) may include a glue tape.

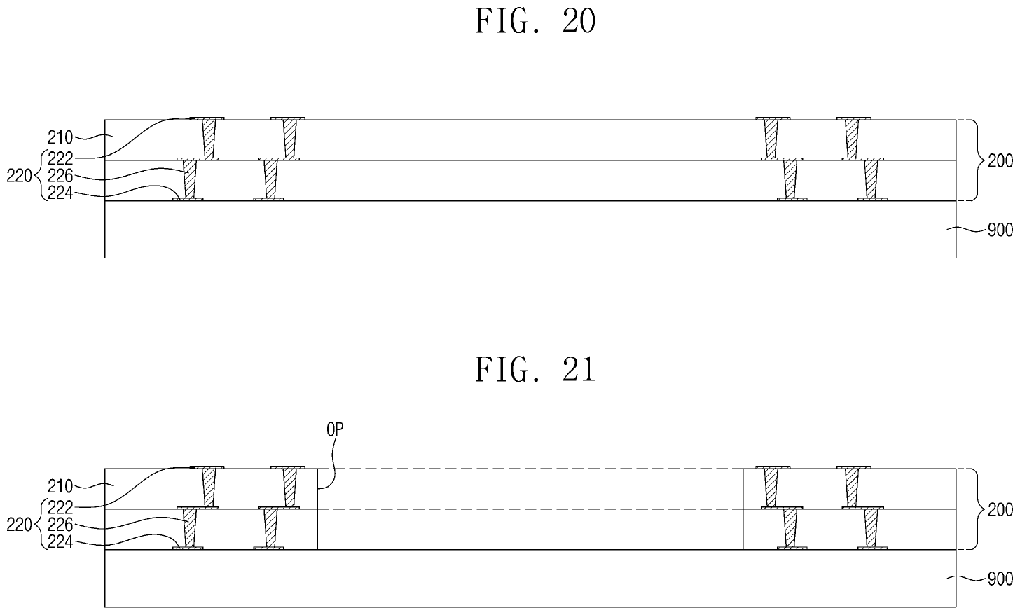

Referring to FIG. 21, an opening OP may be formed in the connection substrate 200. A portion of the connection substrate 200 may be removed to form the opening OP to penetrate the connection substrate 200. The opening OP may be formed by, for example, an etching process such as drilling, laser ablation, or laser cutting.

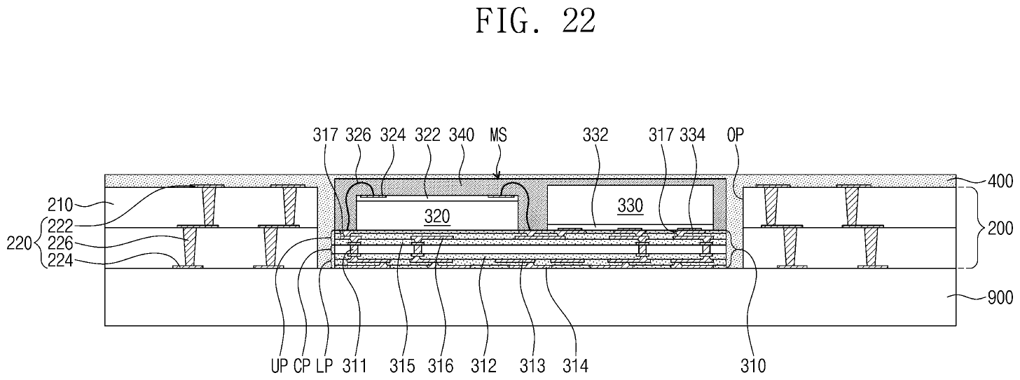

Referring to FIG. 22, a module structure MS may be provided on the carrier substrate 900. The module structure MS may be disposed in the opening OP of the connection substrate 200. The module structure MS may be attached to the carrier substrate 900. In this stage, the module structure MS may be attached to the carrier substrate 900 to allow the interposer substrate 310 to face the carrier substrate 900.

A dielectric member 400 may be formed on the carrier substrate 900. The dielectric member 400 may fill a space between the connection substrate 200 and the module structure MS. For example, a dielectric material may be injected into a space between the connection substrate 200 and the module structure MS, and the dielectric material may be cured to form the dielectric member 400. The dielectric member 400 may include a prepreg, a thermosetting film such as AJINOMOTO BUILD-UP FILM® (ABF), a glass epoxy laminate such as flame retardant 4 (FR-4), or bismaleimide triazine (BT). In an embodiment, the dielectric member 400 may include a dielectric polymer, such as polyimide (PI).

According to some embodiments, the dielectric member 400 may be formed to cover the module structure MS. In addition, a portion of the dielectric member 400 may be provided to cover a top surface of the connection substrate 200. Thus, the upper pads 222 of the connection substrate 200 may not be exposed. In an embodiment, the dielectric member 400 may expose at least a portion of the top surface of the connection substrate 200.

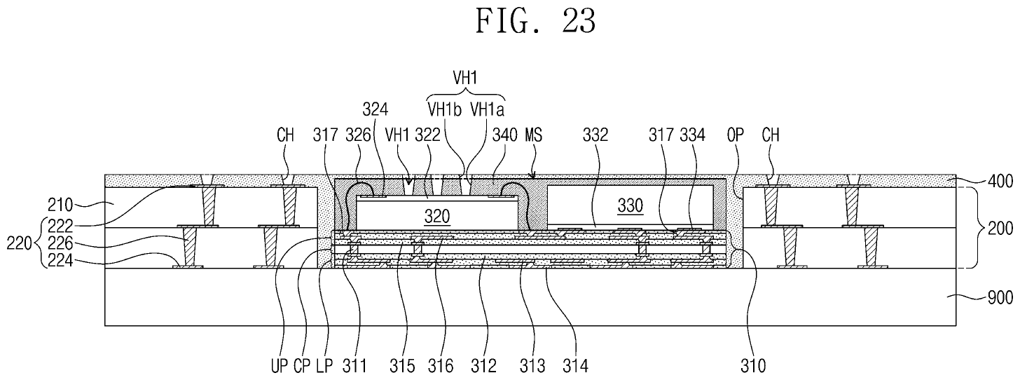

Referring to FIG. 23, a patterning process may be performed on the dielectric member 400 and the molding layer 340. The patterning process may form connection holes CH that expose the upper pads 222 of the connection substrate 200 and form first vertical holes VH1 that expose a top surface of the first semiconductor chip 320. When the module structure MS has a first thermal radiation member 523, the first vertical holes VH1 may expose the first thermal radiation member 523. The connection holes CH may vertically penetrate the dielectric member 400 to expose the upper pads 222. The first vertical holes VH1 may vertically penetrate the dielectric member 400 and the molding layer 340, and expose the first semiconductor chip 320. On the first semiconductor chip 320, the first vertical holes VH1 may be formed to penetrate two kinds of medium, or the dielectric member 400 and the molding layer 340. Therefore, in a wet etching process in which an etch selectivity depends on mediums, independent processes may be needed to etch the dielectric member 400 and the molding layer 340.

According to some embodiments of the present inventive concepts, the patterning process may include a laser treatment process. Using the laser treatment process, the dielectric member 400 and the molding layer 340 may be continuously patterned in a single process. In conclusion, it may be possible to provide a simplified method of fabricating a semiconductor package. As a result of the laser treatment process, an inner lateral surface of a first hole VH1a that penetrates the molding layer 340 and an inner lateral surface of a second hole VH1b that penetrates the dielectric member 400 may have a continuous profile.

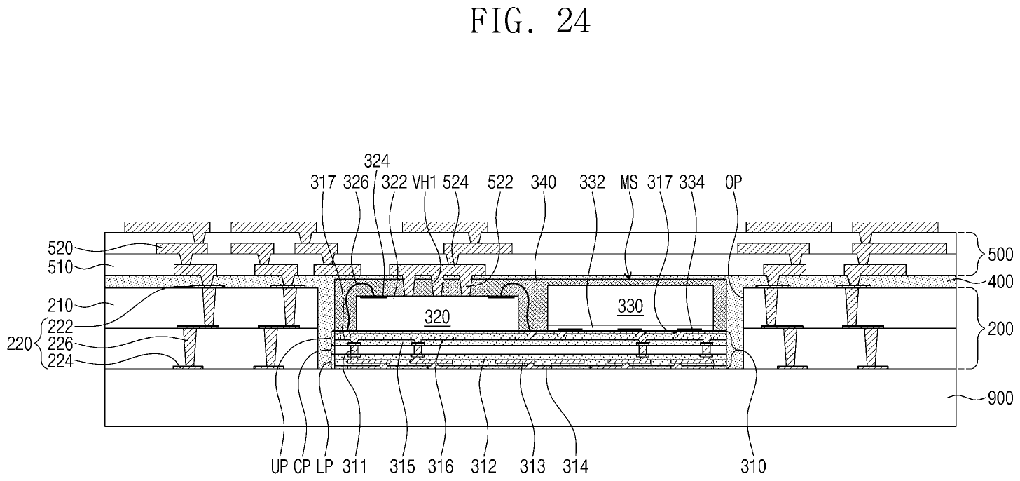

Referring to FIG. 24, a second redistribution substrate 500 may be formed on the dielectric member 400. For example, a conductive layer may be formed on a top surface of the dielectric member 400, and the conductive layer may be patterned to form a second substrate wiring pattern 520. The conductive layer may fill the connection holes CH and the first vertical holes VH1. A dielectric layer may be formed on the top surface of the dielectric member 400 to cover the second substrate wiring pattern 520, the dielectric layer may be patterned to form a second substrate dielectric pattern 510, a conductive layer may be formed on the second substrate dielectric pattern 510, and the conductive layer may be patterned to from a second substrate wiring pattern 520, with the result that one second substrate wiring layer may be formed. The process for forming the second substrate wiring layer may be repeatedly performed to form the second redistribution substrate 500.

Referring back to FIG. 1, the carrier substrate 900 may be removed. Therefore, a bottom surface of the connection substrate 200 may be exposed, and likewise a bottom surface of the module structure MS may be exposed. For example, the lower pads 224 of the connection substrate 200 may be exposed, and first interposer pads 314 of the lower buildup portion LP of the interposer substrate 310 may be exposed.

A first redistribution substrate 100 may be formed below the connection substrate 200 and the module structure MS. For example, a dielectric layer may be formed on the bottom surface of the connection substrate 200 and the bottom surface of the module structure MS, the dielectric layer may be patterned to form a first substrate dielectric pattern 110, a conductive layer may be formed on the first substrate dielectric pattern 110, and the conductive layer may be patterned to form a first substrate wiring pattern 120, with the result that a first substrate wiring layer may be formed. The process for forming the first substrate wiring layer may be repeatedly performed to form the first redistribution substrate 100. Substrate pads 122 may be defined to indicate the first substrate wiring pattern 120 provided in a lowermost first substrate wiring layer. A substrate protection layer 130 covering the substrate pads 122 may be formed on the first substrate wiring layers.

The substrate protection layer 130 may be patterned to expose the substrate pads 122. External terminals 150 may be attached to the substrate pads 122.

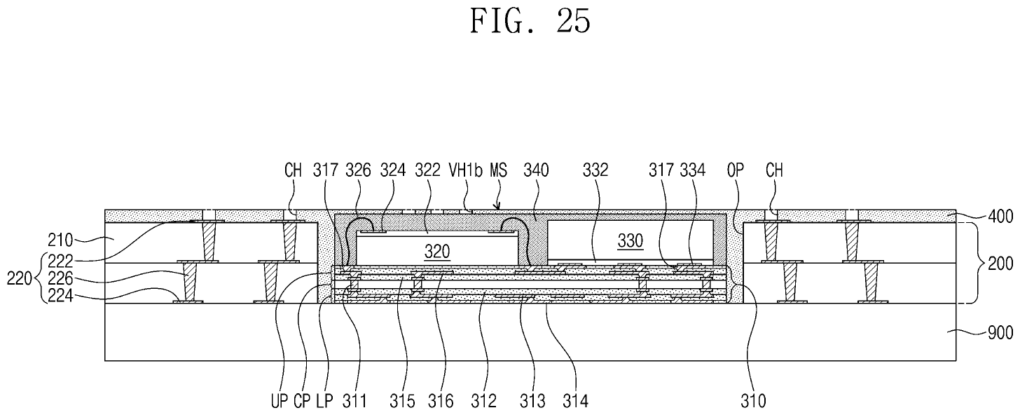

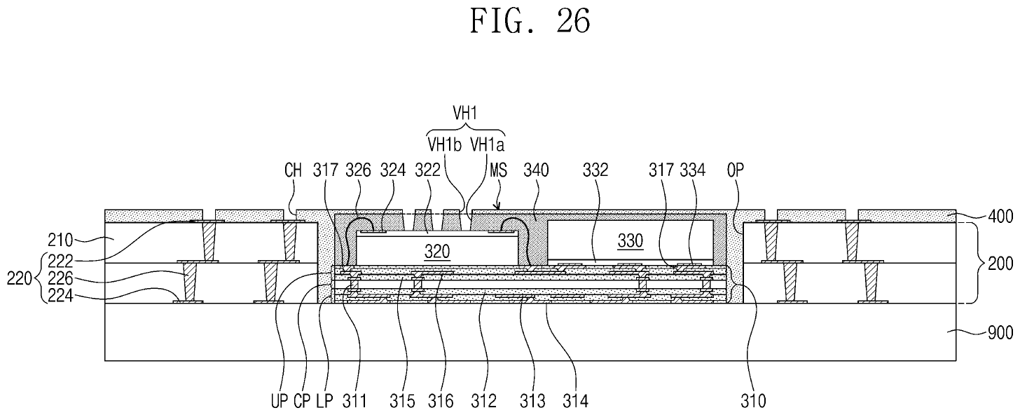

FIG. 25 and FIG. 26 illustrate cross-sectional views showing a method of fabricating a semiconductor package according to some embodiments of the present inventive concepts.

Referring to FIG. 25, a resultant structure of FIG. 22 may be provided. The dielectric member 400 may include a photo-imageable dielectric.

A first patterning process may be performed on the dielectric member 400. The first patterning process may form connection holes CH that expose the upper pads 222 of the connection substrate 200 and second holes VH1b that expose a top surface of the molding layer 340 on the first semiconductor chip 320. The connection holes CH may vertically penetrate the dielectric member 400 to expose the upper pads 222. The second holes VH1b may vertically penetrate the dielectric member 400 to expose the molding layer 340. The first patterning process may include an exposure process and a development process. As a result of the first patterning process, the connection holes CH and the second holes VH1b may be formed to have inner lateral surfaces that are perpendicular to the top surface of the carrier substrate 900. For example, the connection holes CH and the second holes VH1b may have widths that are constant in a vertical direction.

Referring to FIG. 26, a second patterning process may be performed on the molding layer 340. The second patterning process may be performed on the top surface of the molding layer 340 exposed by the second holes VH1b. In order to pattern the molding layer 340 including an epoxy molding compound (EMC), the second patterning process may be performed by a laser treatment process. The second patterning process may form first holes VH1a that expose the top surface of the first semiconductor chip 320. When the module structure MS has a first thermal radiation member 523, the first holes VH1a may expose the first thermal radiation member 523. The first hole VH1a and the second holes VH1b may be vertically connected to constitute first vertical holes VH1 that vertically penetrate the dielectric member 400 and the molding layer 340 to expose the first semiconductor chip 320. As a result of the second patterning process, the first holes VH1a may have inner lateral surfaces that are inclined to the top surface of the carrier substrate 900. For example, the first holes VH1a may have widths that decrease with decreasing distance from the carrier substrate 900. The first hole VH1a and the second hole VH1b may have inclined inner lateral surfaces.

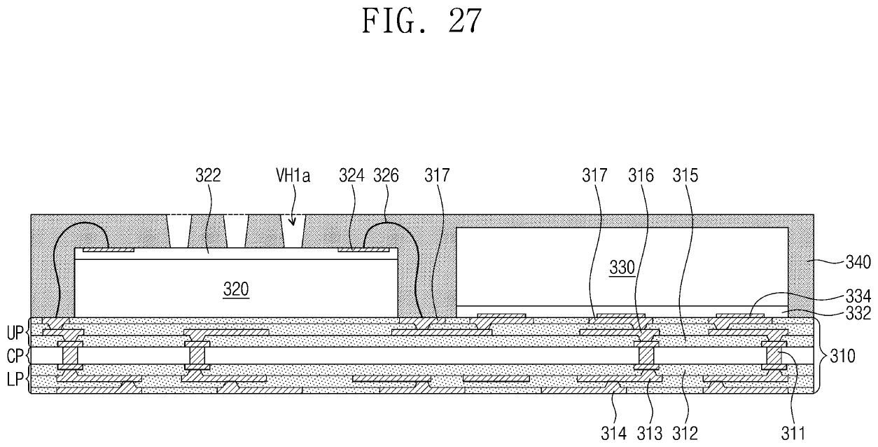

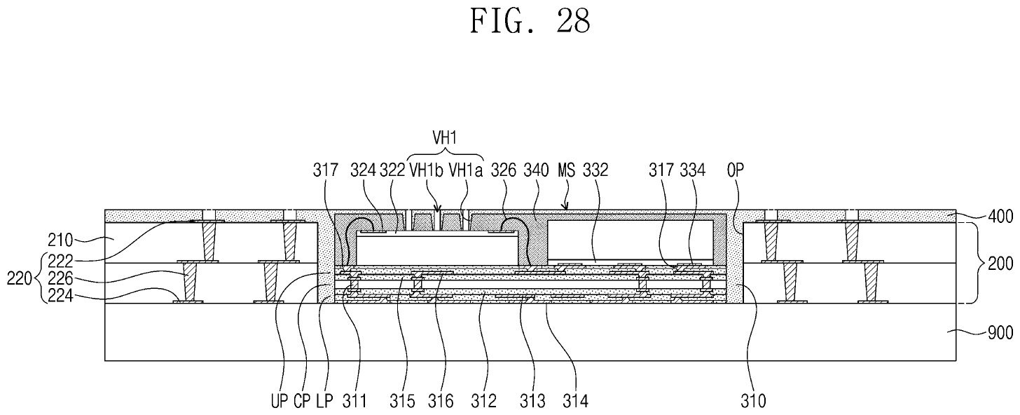

Given a structure according to FIG. 26, processes discussed with reference to FIG. 1 and FIG. 24 may be performed. For example, a second redistribution substrate 500 may be formed on the dielectric member 400, the carrier substrate 900 may be removed, and a first redistribution substrate 100 may be formed below the connection substrate 200 and the module structure MS. FIG. 27 and FIG. 28 illustrate cross-sectional views showing a method of fabricating a semiconductor package according to some example embodiments of the present inventive concepts.

Referring to FIG. 27, a third patterning process may be performed on a resultant structure of FIG. 19. The third patterning process may be performed on the molding layer 340. To pattern the molding layer 340 including an epoxy molding compound (EMC), the third patterning process may be performed by a laser treatment process. The third patterning process may form first holes VH1a that expose the top surface of the first semiconductor chip 320. When the module structure MS has a first thermal radiation member 523, the first holes VH1a may expose the first thermal radiation member 523. As a result of the third patterning process, the first holes VH1a may have inner lateral surfaces that are inclined to the top surface of the carrier substrate 900. For example, the first holes VH1a may have widths that decrease with decreasing distance from the carrier substrate 900.

Processes discussed with reference to FIG. 20 and FIG. 21 may be performed to form a connection substrate 200 on the carrier substrate 900.

Referring to FIG. 28, a module structure MS may be provided on the carrier substrate 900. A dielectric member 400 may be formed on the carrier substrate 900. The process for providing the module structure MS and the process for forming the dielectric member 400 may be substantially the same as or similar to those discussed with reference to FIG. 22. On the module structure MS, the dielectric member 400 may formed to fill the first holes VH1a. The dielectric member 400 may include a photo-imageable dielectric.

A fourth patterning process may be performed on the dielectric member 400. The fourth patterning process may form connection holes CH that expose the upper pads 222 of the connection substrate 200 and second holes VH1b that expose the top surface of the first semiconductor chip 320. The second holes VH1b may vertically penetrate the first holes VH1a.

For example, when viewed in plan, the second holes VH1b may be positioned within the first holes VH1a. When the module structure MS has a first thermal radiation member 523, the second holes VH1b may expose the first thermal radiation member 523. The fourth patterning process may include an exposure process and a development process. As a result of the fourth patterning process, the connection holes CH and the second holes VH1b may be formed to have inner lateral surfaces that are perpendicular to the top surface of the carrier substrate 900. For example, the connection holes CH and the second holes VH1b may have widths that are constant in a vertical direction.

Given a structure according to FIG. 28, processes discussed with reference to FIGS. 1 and 24 may be performed. For example, a second redistribution substrate 500 may be formed on the dielectric member 400, the carrier substrate 900 may be removed, and a first redistribution substrate 100 may be formed below the connection substrate 200 and the module structure MS.

In a semiconductor package according to some embodiments of the present inventive concepts, vias may connect a semiconductor chip to a via connection pattern of a second redistribution substrate. The vias may be used as heat paths for conducting heat generated from the semiconductor chip. For example, the vias may conduct the heat received from the semiconductor chip to the via connection pattern, and the heat may be discharged through the via connection pattern to an upside of the second redistribution substrate. Therefore, a semiconductor package may have an improved thermal radiation efficiency.

In addition, as the via connection pattern downwardly covers the semiconductor chip, the via connection pattern may shield the semiconductor chip from electromagnetic waves that are directed toward the semiconductor chip from outside or electromagnetic waves that are directed toward the outside from the semiconductor chip. It may thus be possible to provide a semiconductor package with improved protection from electromagnetic interference and improved electrical properties.

Although the present inventive concepts have been described in connection with some embodiments of the present inventive concepts illustrated in the accompanying drawings, it will be understood by one of ordinary skill in the art that variations in form and detail may be made therein without departing from the spirit and essential feature of the present inventive concepts. Embodiments should thus be considered illustrative and not restrictive.

What is claimed is:

1. A semiconductor package, comprising:
a lower redistribution substrate;
a module structure on the lower redistribution substrate;
a connection substrate on the lower redistribution substrate and at sides of the module structure;
a dielectric member on the lower redistribution substrate between the connection substrate and the module structure; and
an upper redistribution substrate on the dielectric member,
wherein the module structure includes:
an interposer substrate;
a first semiconductor chip wire-bonded to the interposer substrate; and
a molding layer on the interposer substrate and covering the first semiconductor chip,
wherein the molding layer and the dielectric member include different materials, and
wherein a first via in a first vertical hole vertically penetrates the dielectric member and the molding layer, the first via connecting a wiring pattern of the upper redistribution substrate to a top surface of the first semiconductor chip.

2. The semiconductor package of claim 1, wherein the first vertical hole includes:
a first hole that penetrates the molding layer; and
a second hole that penetrates the dielectric member, and
wherein a first inner lateral surface of the first hole and a second inner lateral surface of the second hole are coplanar with each other and inclined to the top surface of the first semiconductor chip.

3. The semiconductor package of claim 1, wherein the first vertical hole includes:
a first hole that penetrates the molding layer; and
a second hole that penetrates the dielectric member, and
wherein a first inner lateral surface of the first hole and a second inner lateral surface of the second hole are inclined to each other.

4. The semiconductor package of claim 3, wherein
the first inner lateral surface of the first hole is inclined to the top surface of the first semiconductor chip at a first angle, and
the second inner lateral surface of the second hole is inclined to the top surface of the first semiconductor chip at a second angle different than the first angle.

5. The semiconductor package of claim 4, wherein the second inner lateral surface of the second hole is perpendicular to the top surface of the first semiconductor chip.

6. The semiconductor package of claim 1, wherein the dielectric member fills a space between the connection substrate and the module structure and covers the connection substrate and the module structure, and
a portion of the dielectric member extends between the first via and the molding layer.

7. The semiconductor package of claim 6, wherein
a bottom surface of the portion of the dielectric member is level with a bottom surface of the first via, and
the portion of the dielectric member separates the molding layer from the first via.

8. The semiconductor package of claim 6, wherein an inner lateral surface of the first vertical hole is perpendicular to the top surface of the first semiconductor chip.

9. The semiconductor package of claim 1, wherein
the molding layer includes an epoxy molding compound (EMC), and
the dielectric member includes a thermosetting film or a photo-imageable dielectric.

10. The semiconductor package of claim 1, wherein the module structure further includes a thermal radiation member on the top surface of the first semiconductor chip, and
wherein the first via is coupled to a top surface of the thermal radiation member.

11. The semiconductor package of claim 1, wherein
the module structure further includes a second semiconductor chip face-down disposed on the interposer substrate,
the molding layer covers the first semiconductor chip and the second semiconductor chip on the interposer substrate, and
the semiconductor package further comprises a second via in a second vertical hole that vertically penetrates the dielectric member and the molding layer, the second via connecting the wiring pattern of the upper redistribution substrate to the second semiconductor chip.

12. A semiconductor package, comprising:
a lower redistribution substrate;
a module structure on the lower redistribution substrate;
an upper redistribution substrate on the lower redistribution substrate;
a connection substrate between the lower redistribution substrate and the upper redistribution substrate, and at sides of the module structure; and
a dielectric member disposed between the connection substrate and the module structure and disposed between the module structure and the upper redistribution substrate,
wherein the module structure includes:
an interposer substrate;
a first semiconductor chip and a second semiconductor chip on the interposer substrate; and
a molding layer that covers the first semiconductor chip and the second semiconductor chip on the interposer substrate,
wherein the first semiconductor chip is wire-bond mounted on the interposer substrate,
wherein the second semiconductor chip is face-down disposed on the interposer substrate, and
wherein a wiring pattern of the upper redistribution substrate includes a first via that vertically penetrates the dielectric member and the molding layer to come into connection with a top surface of at least one of the first semiconductor chip or the second semiconductor chip.

13. The semiconductor package of claim 12, wherein a width of the first via decreases with decreasing distance from the interposer substrate.

14. The semiconductor package of claim 12, wherein
a first width of the first via in the dielectric member is uniform, and
a second width of the first via in the molding layer decreases with decreasing distance from the interposer substrate.

15. The semiconductor package of claim 12, wherein
a portion of the dielectric member vertically penetrates the molding layer to come into contact with the top surface of the second semiconductor chip,
the first via penetrates the portion of the dielectric member to come into connection with the top surface of the second semiconductor chip, and
the portion of the dielectric member separates the molding layer from the first via.

16. The semiconductor package of claim 15, wherein a width of the first via is uniform.

17. The semiconductor package of claim 12, wherein the first via vertically penetrates the dielectric member and the molding layer to come into connection with the top surface of the second semiconductor chip, and
the wiring pattern of the upper redistribution substrate further includes a second via that vertically penetrates the dielectric member and the molding layer to come into connection with the top surface of the first semiconductor chip.

18. The semiconductor package of claim 12, further comprising a thermal radiation member on the top surface of the second semiconductor chip,
wherein the first via is connected to a top surface of the thermal radiation member.

19. The semiconductor package of claim 12, wherein
the dielectric member includes a material different from a material of the molding layer, and
the dielectric member includes a thermosetting firm or a photo-imageable dielectric.

20. A semiconductor package, comprising:
a lower redistribution substrate;
a connection substrate on the lower redistribution substrate, wherein the connection substrate has an opening that vertically penetrates the connection substrate;
a module structure on the lower redistribution substrate and in the opening of the connection substrate;
a dielectric member on the lower redistribution substrate and covering the module structure; and
an upper redistribution substrate on the dielectric member,
wherein the module structure includes:
an interposer substrate formed of glass;
a first semiconductor chip wire-bonded to the interposer substrate;
a thermal radiation member on a top surface of the first semiconductor chip and electrically insulated from the first semiconductor chip;
a second semiconductor chip on the interposer substrate and spaced apart from the first semiconductor chip; and
a molding layer on the interposer substrate and covering the first semiconductor chip and the second semiconductor chip,
wherein a wiring pattern of the upper redistribution substrate includes a first via that vertically penetrates the dielectric member and the molding layer to be coupled to one of the thermal radiation member or a rear surface of the second semiconductor chip,
wherein a first width of the first via in the dielectric member is uniform, and
wherein a second width of the first via in the molding layer decreases with decreasing distance from the interposer substrate.
